(19) United States
(12) Patent Application Publication
(10) Pub. No.: US 2025/0293122 A1
(43) Pub. Date: Sep. 18, 2025

(54) MULTI-DIE ASSEMBLIES WITH GLASS SUPPORT STRUCTURES

(71) Applicant: Intel Corporation, Santa Clara, CA (US)

(72) Inventors: Robert Alan May, Chandler, AZ (US); Yuxin Fang, Chandler, AZ (US); Lilia May, Chandler, AZ (US); Hiroki Tanaka, Gilbert, AZ (US); Jason M. Gamba, Gilbert, AZ (US); Tarek A. Ibrahim, Mesa, AZ (US); Siddharth K. Alur, Chandler, AZ (US)

(73) Assignee: Intel Corporation, Santa Clara, CA (US)

(21) Appl. No.: 18/602,166

(22) Filed: Mar. 12, 2024

(51) Int. Cl. H01L 23/482; H01L 23/00; H01L 23/498; H01L 25/065

(52) U.S. Cl. CPC H01L 23/4821; H01L 23/49816; H01L 24/08; H01L 24/16; H01L 25/0655; H01L 2224/08146; H01L 2224/08155; H01L 2224/16146; H01L 2224/16157; H01L 2924/01029; H01L 2924/1431; H01L 2924/1434; H01L 2924/15311

(57) ABSTRACT

A microelectronic assembly includes a bridge die embedded in a substrate. The substrate is over a support structure. A via in the substrate between the bridge component and the support structure includes a first end and a second end, where the first end is closer to the support structure than the second end, and the first end has a greater width than a width of the second end. The support structure includes a through-support structure via (TSSV) including a conductive material and a dielectric filler. The TSSV is joined to the via in the substrate.

### BACKGROUND

Integrated circuit (IC) devices (e.g., dies) can be coupled together in a multi-die IC package to integrate features or functionality and to facilitate connections to other components, such as package substrates. IC packages may include an embedded multi-die interconnect bridge (EMIB) for coupling two or more IC dies.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, not by way of limitation, in the figures of the accompanying drawings.

FIG. 1A is a side, cross-sectional view of an example microelectronic assembly, in accordance with various embodiments.

FIG. 1B is an example zoomed view of a portion of FIG. 1A, in accordance with various embodiments.

FIG. 2 is a flow diagram of an example process for manufacturing the microelectronic assembly of FIG. 1A, in accordance with various embodiments.

FIGS. 3A-3T are side, cross-sectional views of various stages in the example process for manufacturing the microelectronic assembly of FIG. 1A, in accordance with various embodiments.

FIGS. 4A-4D are example zoomed views of portions of FIG. 3T, in accordance with various embodiments.

FIG. 5 is a top view of a wafer and dies that may be included in a microelectronic assembly, in accordance with any of the embodiments disclosed herein.

FIG. 6 is a cross-sectional side view of an IC device that may be included in a microelectronic assembly, in accordance with any of the embodiments disclosed herein.

FIG. 7 is a cross-sectional side view of an IC device assembly that may include a microelectronic assembly, in accordance with any of the embodiments disclosed herein.

FIG. 8 is a block diagram of an example electrical device that may include a microelectronic assembly, in accordance with any of the embodiments disclosed herein.

### DETAILED DESCRIPTION

Scaling of features in ICs has been a driving force behind an ever-growing semiconductor industry and emerging applications in fields such as big data, artificial intelligence, mobile communications, and autonomous driving. Scaling to smaller and smaller features enables increased densities of functional units on the limited real estate of semiconductor chips. For example, shrinking transistor size allows incorporation of an increased number of memory or logic devices on a chip, leading to the fabrication of products with increased capacity. The drive for the ever-increasing capacity, however, is not without issue. The necessity to optimize fabrication and performance of each component (e.g., of each transistor) is becoming increasingly significant.

Parallel to optimizations at the transistor level, advanced IC packaging landscape is rapidly evolving to accommodate performance expectations and requirements of shrinking transistor size. Multiple IC dies are now commonly coupled together in a multi-die IC package to integrate features or functionality and to facilitate connections to other components, such as package substrates. For example, IC packages may include an EMIB for coupling two or more IC dies.

Integration of multiple dies in a single IC package has tremendous benefits, but it adds additional complexities due to placing materials with different material properties in close proximity to one another. When an IC package undergoes processing involving various temperatures and pressure loads, individual materials within the package may behave differently from one another, resulting in out of plane deformation of various layers, known as package warpage.

One approach for addressing package warpage is to include at least one rigid core layer in a dielectric material of a substrate in order to provide mechanical rigidity to the substrate. However, recent trends in electronic devices such as mobile phones, multimedia devices and computer notebooks include demands for slimmer and lighter device designs. Coreless substrates are adopted for fabrication of components in such electronic devices to enable a thinner profile of the components.

Unlike a core-containing substrate, a coreless substrate does not have a core layer to provide flexural rigidity against package warpage. As such, coreless substrates are more susceptible to warpage during manufacturing processes when compared to conventional substrates with core layers. For example, Surface Mount Technology (SMT) processes typically involve subjecting package substrates to one or more cycles of heating and cooling, which in turn create expansion and contraction of the substrate. Differences in coefficients of thermal expansion (CTEs) of various materials within the substrate result in different rates of expansion and contraction and hence stress in the substrate. The resulting stress may warp the substrate, leading to problems during component package assembly and/or during surface mount processes performed at Original Equipment Manufacturer (OEM) facilities. Complex IC packages with multiple dies (including but not limited to EMIBs) with different materials in close proximity to one another may be particularly sensitive to stress and warp, rendering it difficult to include coreless substrates in such packages. It is desirable to develop an IC package including a coreless substrate that has improved mechanical support.

As described herein, a support structure is included in an IC package. A first side of the support structure can be joined to a coreless substrate by an adhesive layer. The support structure may include a glass structure, a glass layer, or a glass material. The support structure can provide mechanical support for the coreless substrate and can increase flexural rigidity against package warpage. The support structure may include a through-support structure via (TSSV), allowing for an electrical connection to be made through the support structure between an electrically conductive material in the substrate and an electrically conductive material on an opposite side of the support structure. The TSSV can be directly coupled to the electrically conductive material in the substrate without requiring the formation of a solder bond, allowing for design simplification. The TSSV can include an electrically conductive material and a dielectric filler. The filler in the TSSV can reduce risk of potential damage, cracking, or warp in the support structure due to a potential mismatch in thermal expansion of conductive material in the TSSV and the support structure.

As noted above, the support structure may include a glass structure that has TSSVs formed therein. Openings for forming the TSSVs may be formed prior to attaching the glass structure to the substrate, and the openings may be filled in with the conductive material and dielectric filler. The openings may have narrower pitch (e.g., tighter spacing) than is typically possible for packages with cores. For example, if a core is used, holes are typically drilled through the package when forming via connections through the package. The vias in the glass structure can have a narrower pitch than the drilled holes in prior designs, which can improve routing. For example, in some embodiments, the pitch between adjacent TSSVs may be less than or equal to 1 millimeter (for example, between 0.1 and 1 millimeters, or between 0.1 and 0.7 millimeters, or between 0.1 and 0.5 millimeters, or between 0.1 and 0.25 millimeters, or less than or equal to 0.1 millimeters, or any ranges or sub-ranges therebetween).

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. The accompanying drawings are not necessarily drawn to scale. Although many of the drawings illustrate rectilinear structures with flat walls and right-angle corners, this is simply for ease of illustration, and actual devices made using these techniques may exhibit rounded corners, surface roughness, and other features. It is to be understood that such schematic illustrations may not reflect real-life process limitations which may cause the features to not look so “ideal” when any of the structures described herein are examined using, e.g., output of suitable characterization tools such as scanning electron microscopy (SEM) images, transmission electron microscope (TEM) images, or non-contact profilometer data. In such output of suitable characterization tools or images of real structures, possible processing and/or surface defects or features could also be visible, e.g., surface roughness, curvature or profile deviation, pits or scratches, not-perfectly straight edges of materials, tapered vias or other openings, inadvertent rounding of corners or variations in thicknesses of different material layers, occasional screw, edge, or combination dislocations within one or more crystalline regions, and/or occasional dislocation defects of single atoms or clusters of atoms. There may be other defects not listed here but that are common within the field of device fabrication and/or packaging.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. As used herein, a “package” and an “IC package” are synonymous, as are a “die” and an “IC die.” The terms “top” and “bottom” may be used herein to explain various features of the drawings, but these terms are simply for ease of discussion, and do not imply a desired or required orientation. As used herein, the term “insulating” means “electrically insulating,” unless otherwise specified. Throughout the specification, and in the claims, the term “coupled” means a direct or indirect connection, such as a direct electrical, mechanical, or magnetic connection between the things that are connected or an indirect connection, through one or more passive or active intermediary devices. The meaning of “a,” “an,” and “the” include plural references. The meaning of “in” includes “in” and “on.” Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner. The term “circuit” means one or more passive and/or active components that are arranged to cooperate with one another to provide a desired function. The terms “substantially,” “close,” “approximately,” “near,” and “about,” generally refer to being within +/−20% of a target value (e.g., within +/−5 or 10% of a target value) based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

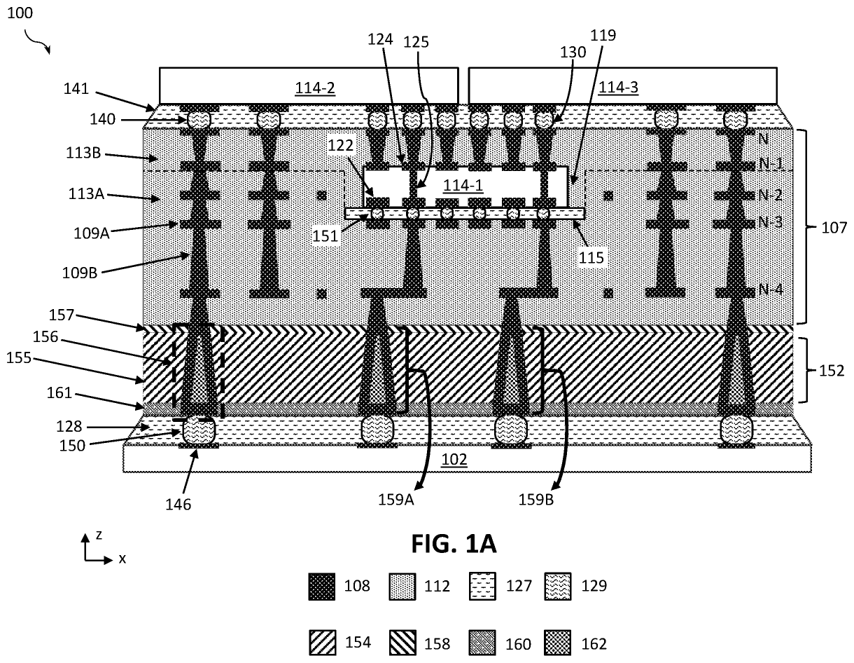

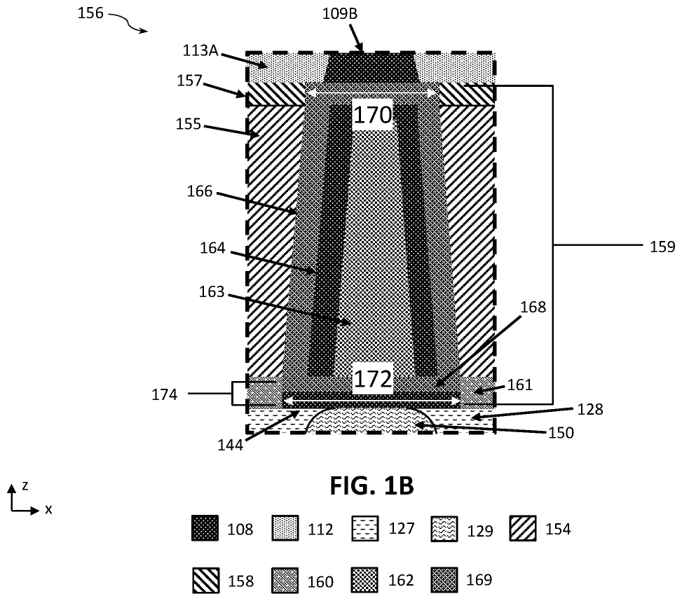

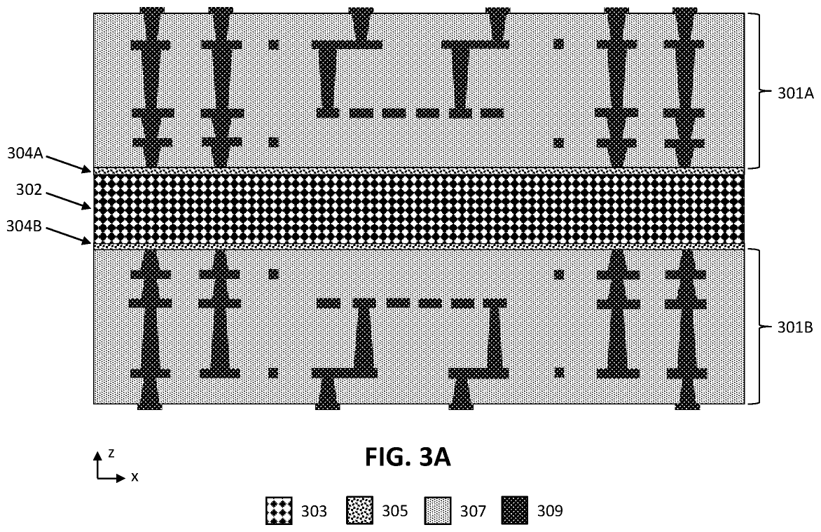

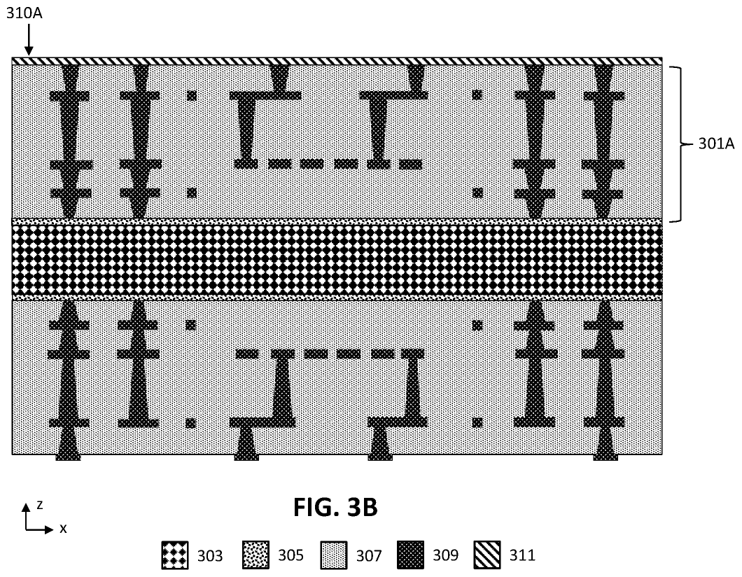

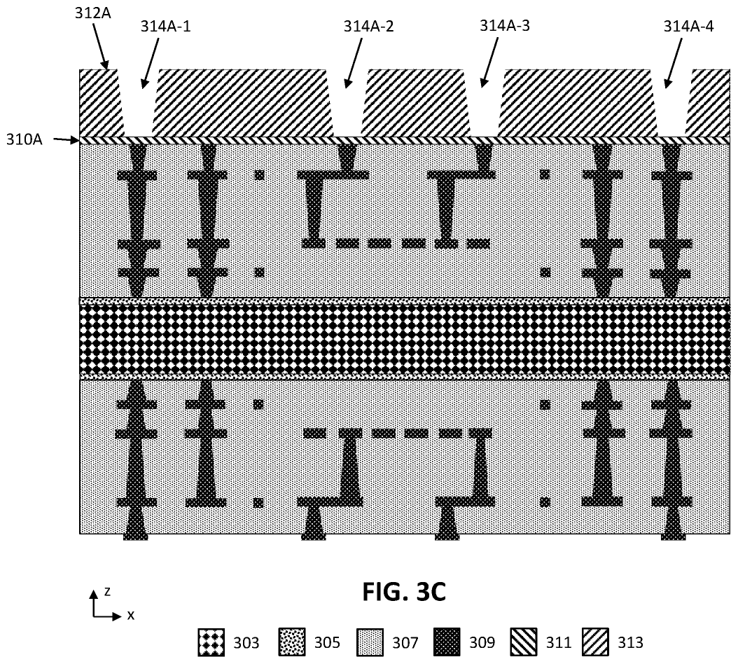

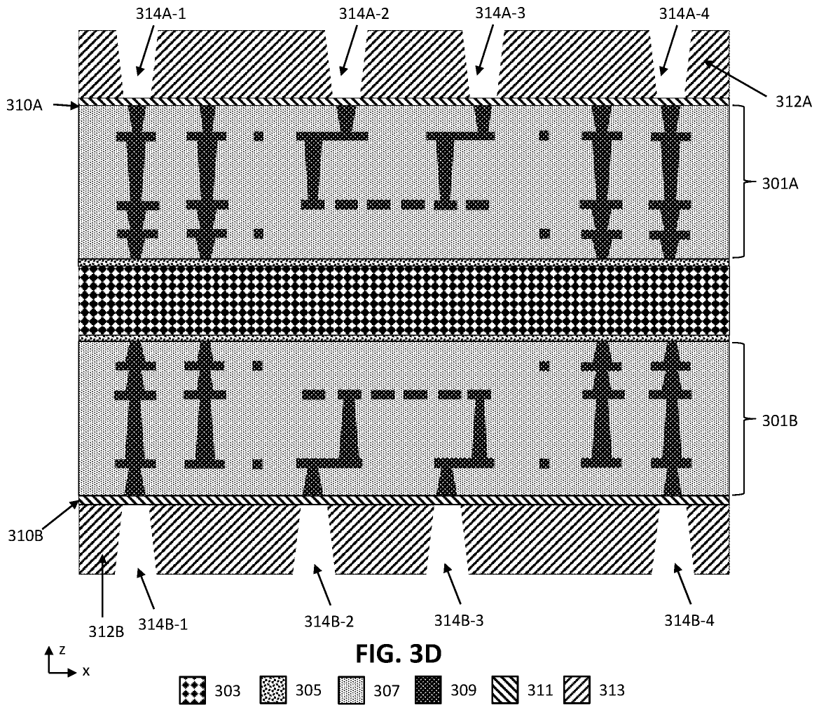

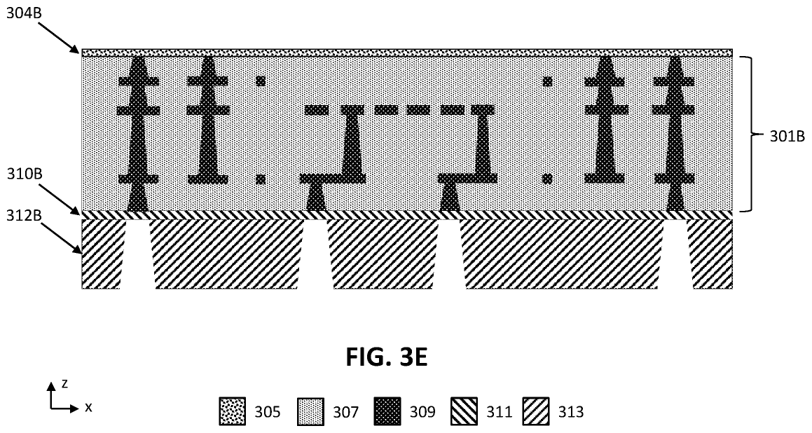

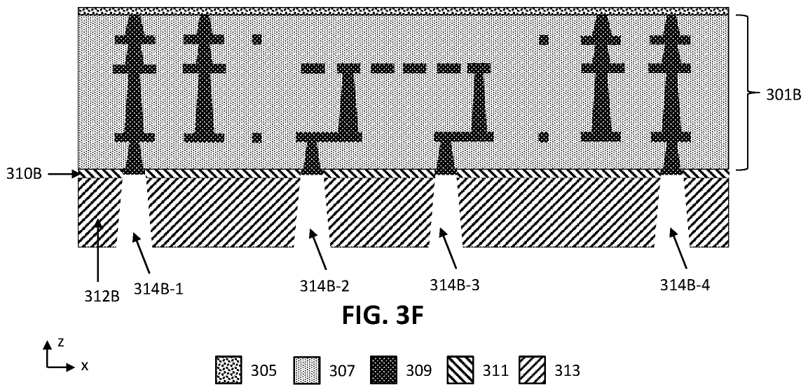

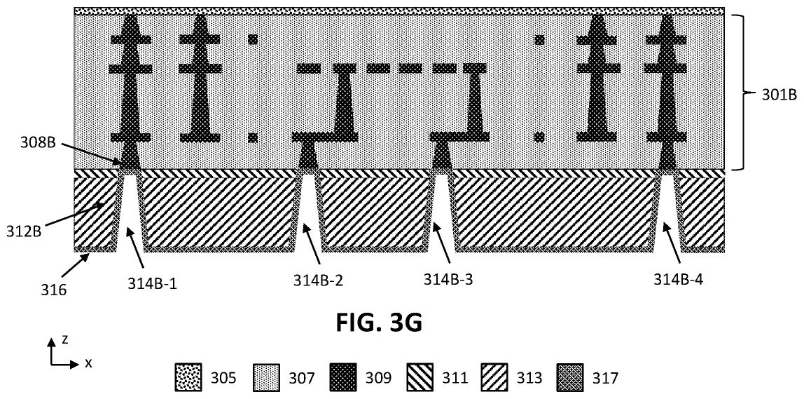

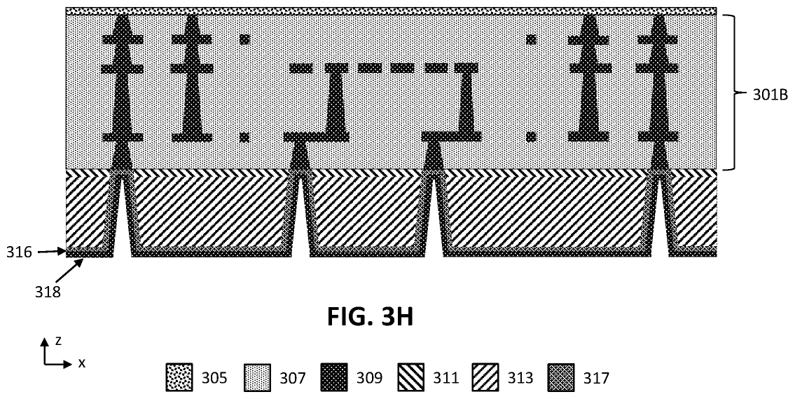

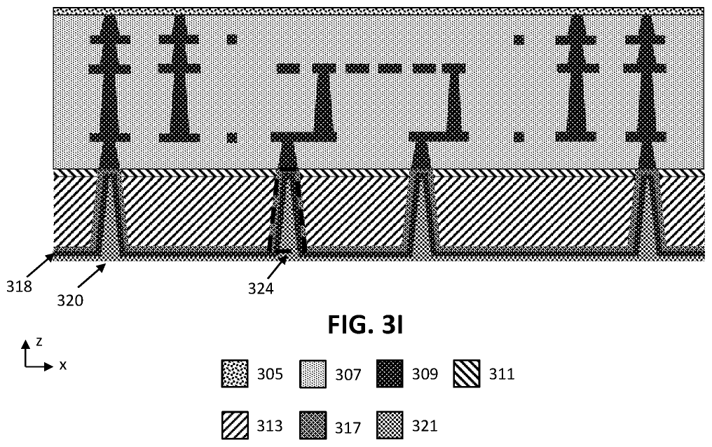

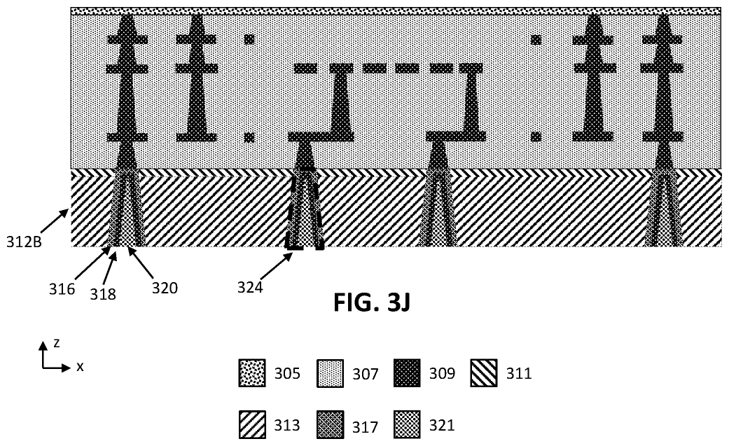

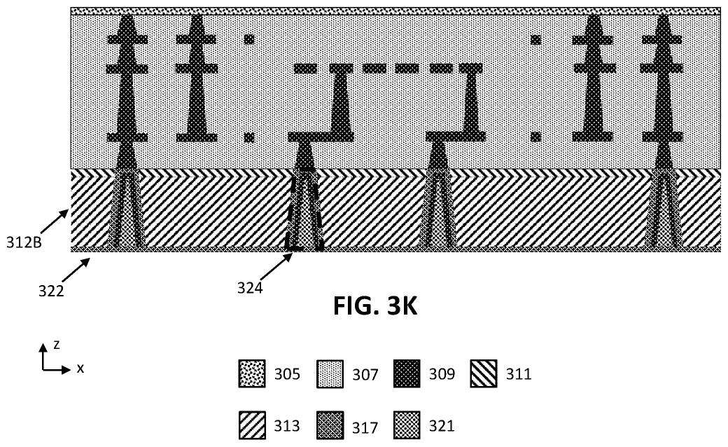

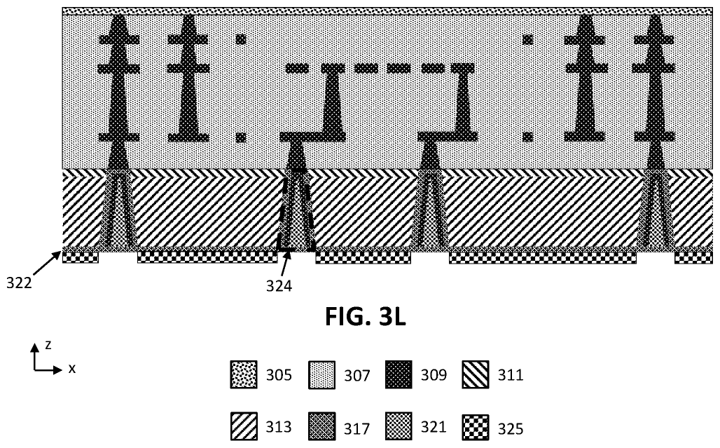

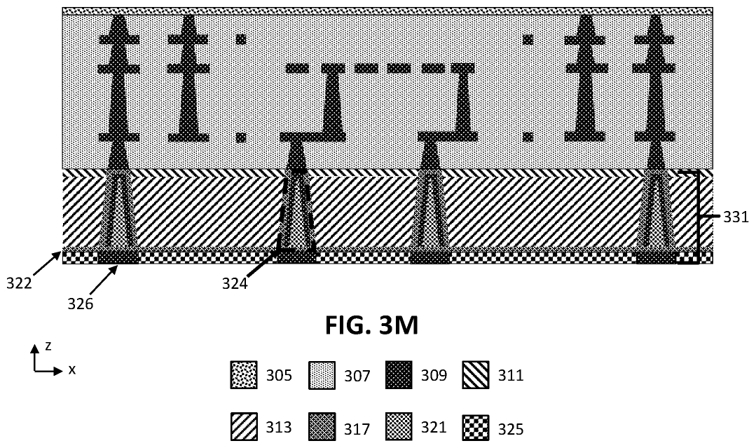

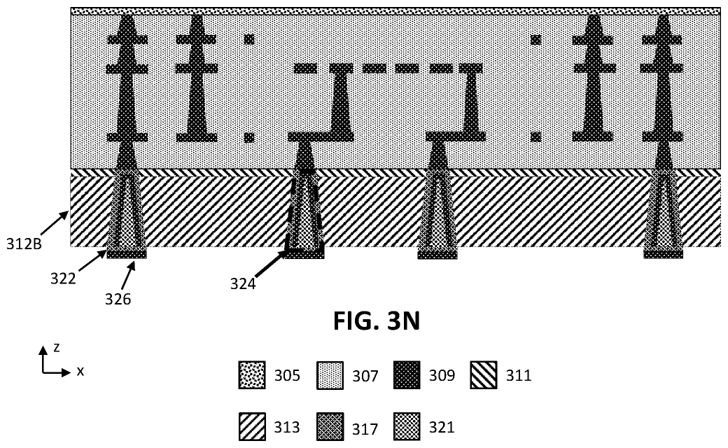

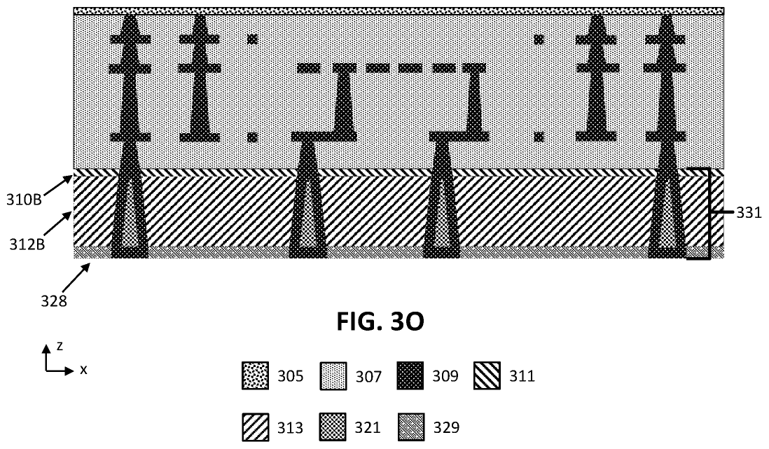

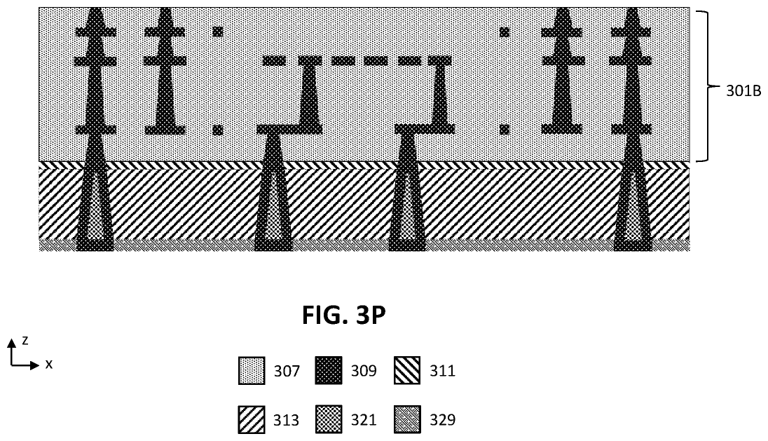

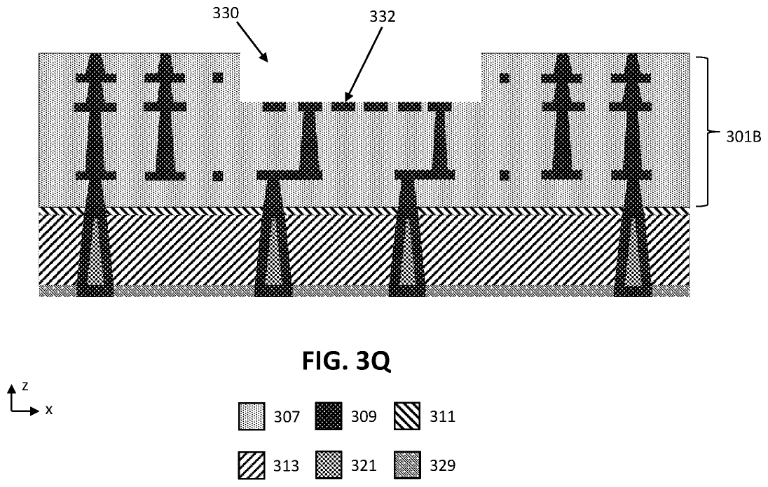

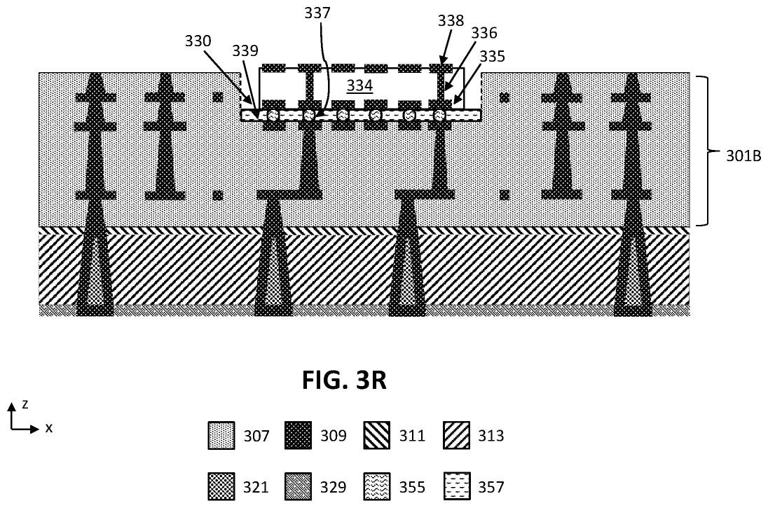

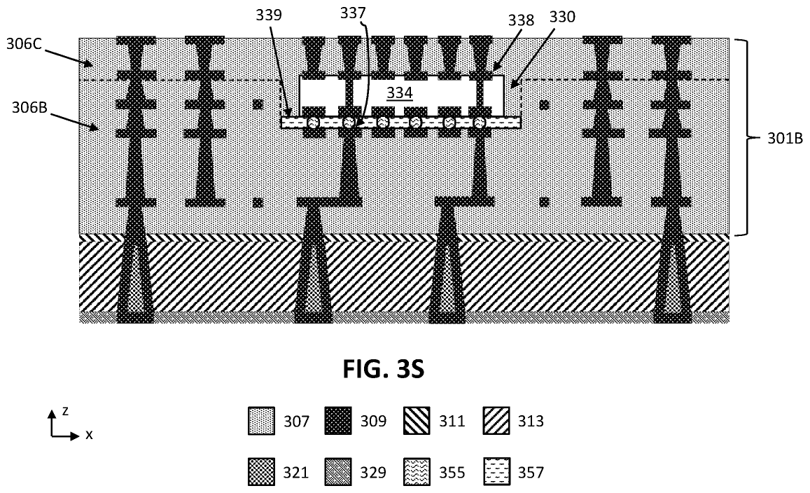

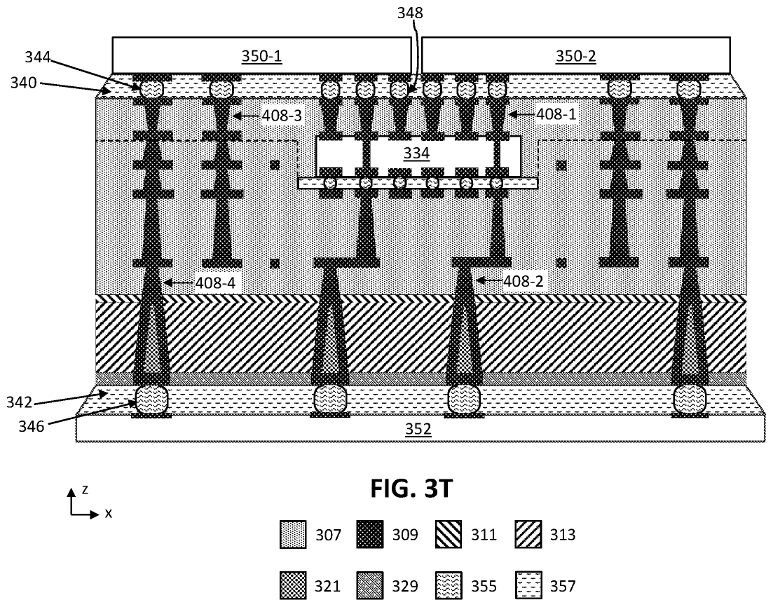

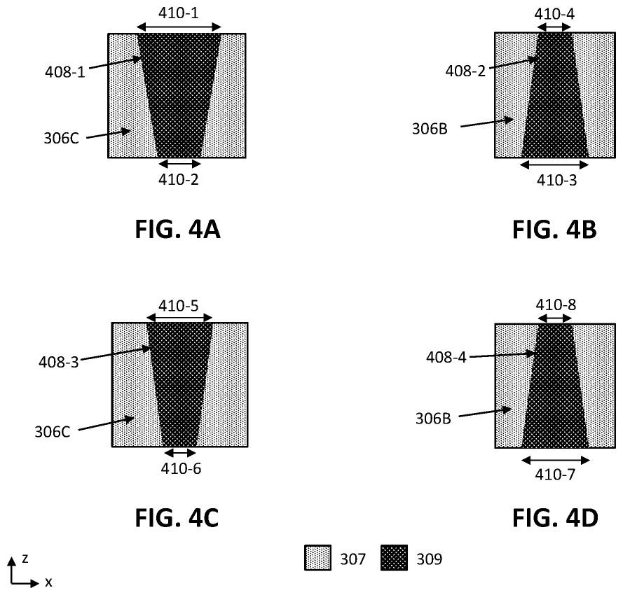

When used to describe a range of dimensions, the phrase “between X and Y” represents a range that includes X and Y. For convenience, the phrase “FIG. 1” may be used to refer to the collection of drawings of FIGS. 1A-1B, “FIG. 3” may be used to refer to the collection of drawings of FIGS. 3A-3T, the phrase “FIG. 4” may be used to refer to the collection of drawings of FIGS. 4A-4D, etc. Although certain elements may be referred to in the singular herein, such elements may include multiple sub-elements. For example, “an insulating material” may include one or more insulating materials.

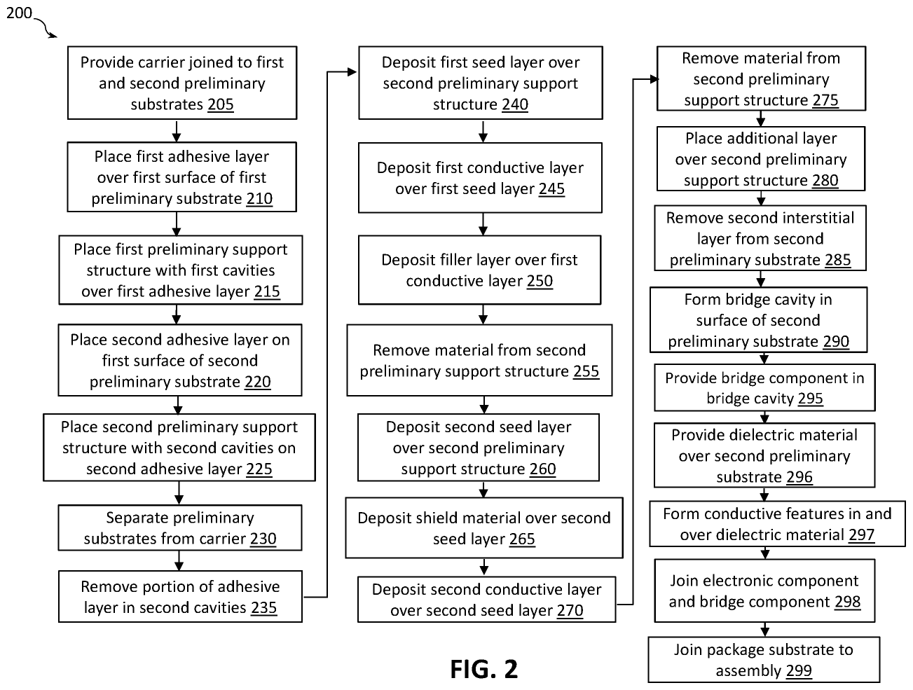

FIG. 1A is a side, cross-sectional view of an example microelectronic assembly, in accordance with various embodiments. The microelectronic assembly 100 may include a substrate 107 with a double-sided bridge die 114-1 that is formed within a cavity 119 in the substrate 107, as illustrated in the process shown in FIG. 2 and FIG. 3. The substrate 107 may include a dielectric material 112 (e.g., a first dielectric material layer 113A and a second dielectric material layer 113B, as shown) and a conductive material 108 (e.g., lines/traces/pads/contacts 109A and vias 109B, as shown), with the conductive material 108 arranged in the dielectric material 112 to provide conductive pathways through the substrate 107. The bridge die 114-1 may be surrounded by the dielectric material 112 of the substrate 107.

The bridge die 114-1 may include a bottom surface with first conductive contacts 122, an opposing top surface with second conductive contacts 124, and vias 125 coupling respective first and second conductive contacts 122, 124. In some embodiments, a pitch of the first conductive contacts 122 on the bridge die 114-1 may be between 25 micrometers and 250 micrometers. As used herein, pitch is measured center-to-center (e.g., from a center of a conductive contact to a center of an adjacent conductive contact). In some embodiments, a pitch of the second conductive contacts 124 on the die 114-1 may be between 25 micrometers and 100 micrometers. The first conductive contacts 122, the second conductive contacts 124, and/or the vias 125 may comprise the conductive material 108 described above, or may comprise a different conductive material.

Dies 114-2, 114-3 may be present above the bridge die 114-1. The dies 114-2, 114-3 may include conductive contacts 122 on the bottom surfaces of the dies (e.g., the surfaces facing towards an upper surface of the substrate 107). The dies 114-1, 114-2, and 114-3 (collectively, dies 114) may include other conductive pathways (e.g., including lines and vias) and/or other circuitry (not shown) coupled to the respective conductive contacts (e.g., conductive contacts 122, 124) on the surfaces of the dies 114. As used herein, the terms “die,” “microelectronic component,” and similar variations may be used interchangeably. As used herein, the terms “interconnect component,” “bridge die,” and similar variations may be used interchangeably. The bridge die 114-1 may be electrically coupled to dies 114-2, 114-3 by die-to-die (DTD) interconnects 130. The DTD interconnects 130 may comprise a conductive material 129. The DTD interconnects 130 are over the upper surface of the substrate 107. In particular, conductive contacts 124 on a top surface of the bridge die 114-1 may be coupled to conductive contacts 122 on bottom surfaces of the dies 114-2, 114-3 by conductive vias 109B through the dielectric material 112 (e.g., the second dielectric material layer 113B) and DTD interconnects 130.

As used herein, a “conductive contact” may refer to a portion of conductive material (e.g., metal) serving as an electrical interface between different components (e.g., part of a conductive interconnect). Conductive contacts may be recessed in, flush with, or extending away (e.g., having a pillar shape) from a surface of a component, and may take any suitable form (e.g., a conductive pad or socket, or portion of a conductive line or via). In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “metal traces,” “lines,” “metal lines,” “wires,” “metal wires,” “trenches,” or “metal trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a photonic IC (PIC), “interconnect” may also describe any element formed of a material that is optically conductive for providing optical connectivity to one or more elements associated with the PIC. In such cases, the term “interconnect” may refer to optical waveguides (e.g., structures that guide and confine light waves), including optical fiber, optical splitters, optical combiners, optical couplers, and optical vias.

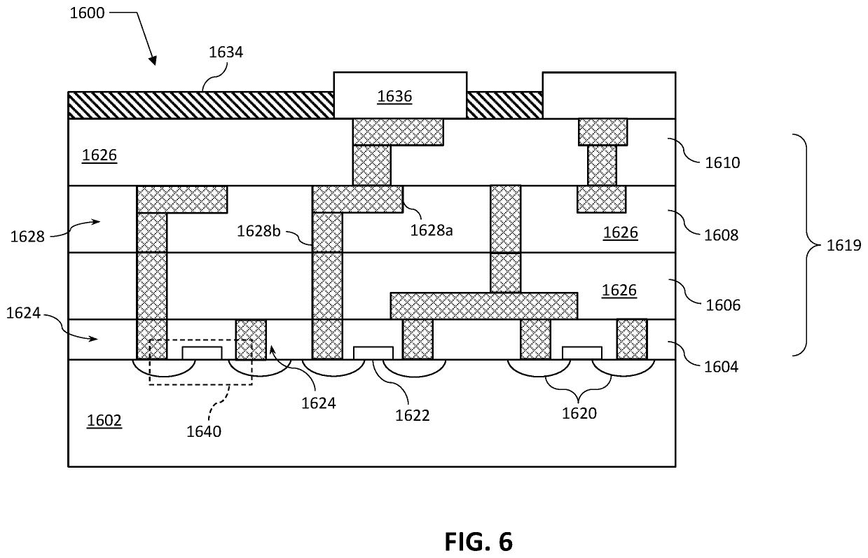

Dies 114 disclosed herein may include an insulating material (e.g., a dielectric material formed in multiple layers, as known in the art) and one or more conductive pathways formed through the insulating material. In some embodiments, the insulating material of a die 114 (e.g., any one or more of the dies 114-1, 114-2, 114-3) may include a dielectric material, such as silicon dioxide, silicon nitride, oxynitride, polyimide materials, glass reinforced epoxy matrix materials, or a low-k or ultra-low-k dielectric (e.g., carbon-doped dielectrics, fluorine-doped dielectrics, porous dielectrics, organic polymeric dielectrics, photo-imageable dielectrics, and/or benzocyclobutene-based polymers). In some embodiments, the insulating material of a die 114 may include a semiconductor material, such as silicon, germanium, or a III-V material (e.g., gallium nitride). The insulating material may further include one or more additional materials. For example, an insulating material may include silicon oxide or silicon nitride. The one or more conductive pathways in a die 114 may include conductive traces and/or conductive vias, and may connect any of the conductive contacts in the die 114 in any suitable manner (e.g., connecting multiple conductive contacts on a same surface or on different surfaces of the die 114). Example structures that may be included in the dies 114 disclosed herein are discussed below with reference to FIG. 6. The conductive pathways in the dies 114 may be bordered by liner materials, such as adhesion liners and/or barrier liners, as suitable. In some embodiments, the die 114 (e.g., any one or more of the dies 114-1, 114-2, 114-3) is a wafer. In some embodiments, the die 114 is a monolithic silicon die, a fan-out or fan-in package die, or a die stack (e.g., wafer stacked, die stacked, or multi-layer die stacked).

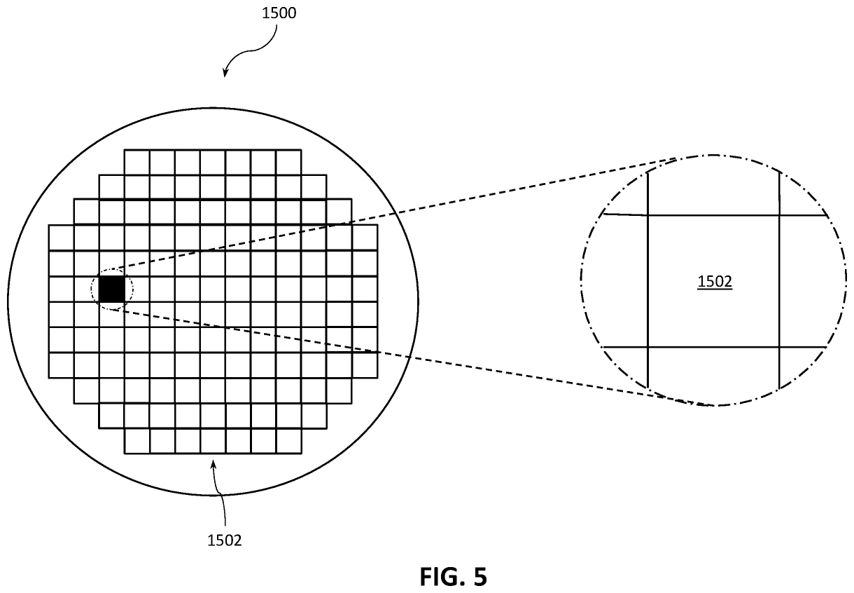

In some embodiments, the die 114 may include conductive pathways to route power, ground, and/or signals to/from other dies 114 included in the microelectronic assembly 100. For example, the bridge die 114-1 may include vias 125, including a conductive material via (such as a metal via, which may be isolated from surrounding silicon or other semiconductor material by a barrier oxide), or other conductive pathways through which power, ground, and/or signals may be transmitted between a package substrate 102 and one or more dies 114 “above” the bridge die 114-1 (e.g., as shown in FIG. 1A, the dies 114-2 and/or 114-3). In some embodiments, the bridge die 114-1 may route power, ground, and/or signals between the dies 114-2 and/or 114-3, or from another portion of the microelectronic assembly 100 to conductive pathways in the substrate 107 by bridge-to-substrate (BTS) interconnects 151. The BTS interconnects 151 may comprise the same or a similar conductive material as the conductive material 129 of the DTD interconnects 130, and/or may comprise a different material. In some embodiments, the bridge die 114-1 may not route power and/or ground to the dies 114-2 and 114-3; instead, the dies 114-2, 114-3 may couple to power and/or ground lines in the package substrate 102 at least in part by substrate-to-package substrate (STPS) interconnects 150, conductive material 108 (e.g., conductive pathways) in the substrate 107, and die-to-substrate (DTS) interconnects 140. The STPS interconnects 150 or the DTS interconnects 140 may comprise the same conductive material 129 as the DTD interconnects 130 or the BTS interconnects 151, or may comprise a different conductive material. In some embodiments, the bridge die 114-1 may be thicker than the dies 114-2, 114-3. In some embodiments, the bridge die 114-1 may be a memory device (e.g., as described below with reference to the die 1502 of FIG. 5), or a high frequency serializer and deserializer (SerDes), such as a Peripheral Component Interconnect (PCI) express. In some embodiments, the bridge die 114-1 may be a processing die, a radio frequency chip, a power converter, a network processor, a workload accelerator, a voltage regulator die, or a security encryptor. In some embodiments, the die 114-2 and/or the die 114-3 may be a processing die, a radio frequency chip, a power converter, a network processor, a workload accelerator, a voltage regulator die, or a security encryptor.

As noted earlier, the dielectric material 112 of the substrate 107 may be formed in layers (e.g., at least the first dielectric material layer 113A and a second dielectric material layer 113B). In some embodiments, the dielectric material 112 may include an organic material, such as an organic build-up film. In some embodiments, the dielectric material 112 may include a ceramic, an epoxy film having filler particles therein, glass, an inorganic material, or combinations of organic and inorganic materials, for example. In some embodiments, the conductive material 108 may include a metal (e.g., copper). In some embodiments, the substrate 107 may include layers of dielectric material 112/conductive material 108, with lines/traces/pads/contacts 109A of conductive material 108 in one layer electrically coupled to lines/traces/pads/contacts 109A of conductive material 108 in an adjacent layer by vias (e.g., 109B) of conductive material 108 extending through the dielectric material 112. Conductive lines/traces/pads/contacts 109A may be referred to herein as “conductive lines,” “conductive traces,” “conductive pads,” or “conductive contacts.” A substrate 107 including such layers may be formed using a printed circuit board (PCB) fabrication technique, for example.

An individual layer of dielectric material 112 (e.g., a first dielectric material layer 113A) may include a cavity 119 and the bridge die 114-1 may be at least partially nested in the cavity 119. The bridge die 114-1 may be surrounded by (e.g., embedded in, encased in, or enclosed in) a next individual layer of dielectric material 112 (e.g., a second dielectric material layer 113B). In some embodiments, a cavity 119 is tapered, narrowing towards a bottom surface of the cavity 119. A cavity 119 may be indicated by a seam between the dielectric material layer 113A and the dielectric material layer 113B. As shown in FIG. 1, in cases where the bridge die 114-1 is partially nested in a cavity 119, a top surface of the bridge die 114-1 may extend above a top surface of dielectric material layer 113A. In cases where the bridge die 114-1 is fully nested in a cavity 119, a top surface of the bridge die 114-1 may be planar with a top surface of dielectric material layer 113A, or may be below a top surface of the dielectric material layer 113A.

The substrate 107 may include N layers of conductive material 108, where N is an integer greater than or equal to one; in the accompanying drawings, the layers are labeled in descending order from the upper surface of the substrate 107 (e.g., layer N, layer N-1, layer N-2, etc.). In particular, as shown in FIG. 1, a substrate 107 may include five metal layers (e.g., N, N-1, N-2, N-3, and N-4). The N metal layer may include conductive contacts 109A at a top surface of the substrate 107 that are coupled to conductive contacts 122 at bottom surfaces of the dies 114-2, 114-3 by DTS interconnects 140. The N-3 metal layer, for example, may include conductive traces 109A having a top surface, an opposing bottom surface, and lateral surfaces extending between the top and bottom surfaces of the conductive traces 109A.

Although a particular number and arrangement of layers of dielectric material 112/conductive material 108 are shown in various ones of the accompanying figures, these particular numbers and arrangements are simply illustrative, and any desired number and arrangement of dielectric material 112/conductive material 108 may be used. Further, although a particular number of layers of dielectric material 112/conductive material 108 are shown in the substrate 107, these layers may represent only a portion of the substrate 107, for example, fewer layers may be present, or further layers may be present (e.g., layers N-5, N-6, etc., of conductive material 108). As shown in FIG. 1, the substrate 107 is a coreless substrate. In some embodiments, the substrate may further include a core. The core may include through core vias, and one or more further layers may be present below the core. The core may be formed of any suitable material, including glass, a fiber-reinforced epoxy, an organic dielectric material, such as an epoxy, or a phenolic resin or polyimide resin reinforced with glass, aramid, or nylon.

The microelectronic assembly 100 may include a support structure 155. The support structure 155 may include a support structure material 154 (e.g., a glass material). The support structure 155 may be joined or coupled to a bottom surface of the substrate 107. In particular, a top surface of the support structure 155 may be coupled to the bottom surface of the substrate 107. One or more intermediary layers may be in between the support structure 155 and the substrate 107. The one or more intermediary layers can include an adhesive layer 157. The adhesive layer 157 can physically couple the support structure 155 and the substrate 107.

The adhesive layer 157 may include an adhesive material 158. In some embodiments, the adhesive material 158 may include an organic material, such as a glue, an epoxy material (e.g., an ultraviolet (UV)-curable epoxy that, upon exposure to UV radiation after deposition, cross-links in place), a polyester, a polyimide, or an acrylic material. In some embodiments, the adhesive material 158 additionally or alternatively includes an inorganic material. The adhesive material 158 may further include one or more organic or inorganic solvents, fillers, plasticizers, reinforcements, and/or additives.

The adhesive layer 157 may have a relatively low thickness (e.g., a low thickness relative to the thickness of the substrate 107 along the z-axis direction in FIG. 1A, or a low thickness relative to the thickness of the support structure 155 along the z-axis direction in FIG. 1A). For example, the adhesive layer 157 may have a thickness of less than 50 micrometers (e.g., between 1 and 50 micrometers in thickness, or between 1 and 25 micrometers in thickness, or between 1 and 20 micrometers in thickness, or between 1 and 10 micrometers in thickness, or any ranges and sub-ranges therebetween). In some embodiments, the adhesive layer 157 may have a thickness of greater than or equal to 50 micrometers. The adhesive layer 157 may have a thickness of less than or equal to 100% of the thickness of the support structure 155 (for example, between 0.1% and 100% of the thickness of the support structure 155, or between 0.1 and 50% of the thickness of the support structure 155, or between 0.1 and 25% of the thickness of the support structure 155, or between 0.1 and 10% of the thickness of the support structure 155, or between 0.1% and 5% of the thickness of the support structure 155, or between 0.1% and 2.5% of the thickness of the support structure 155, or between 0.1% and 1% of the support structure 155, or any ranges or sub-ranges therebetween). In some embodiments, the thickness of the adhesive layer 157 and the thickness of the support structure 155 may be substantially similar, or the thickness of the adhesive layer 157 may be greater than the thickness of the support structure 155. In some embodiments, the thickness of the adhesive layer 157 may vary. For example, the thickness of the adhesive layer 157 over

The adhesive layer 157 may be relatively soft, e.g., less stiff or rigid than the support structure 155. In some embodiments, the adhesive layer 157, or the adhesive material 158, may have a Young's modulus of less than 3 GPa, e.g., between 0.01 and 3 GPa, between 0.01 and 2 GPa, or between 0.01 and 1 GPa, or any ranges or sub-ranges therebetween. In some embodiments, the adhesive layer 157, or the adhesive material 158, may have a Young's modulus of glass of less than 10 GPa, e.g., between 0.01 and 10 GPa, or between 0.01 and 5 GPa, or any ranges or sub-ranges therebetween.

The adhesive layer 157 may be able to be etched relatively rapidly (for example, using a wet etching process, or a dry etching process such as reactive-ion etching, plasma etching, or another ion-bombardment type etching process). The adhesive layer 157 may be able to be etched relatively more rapidly than the support structure 155 for a given etchant (for example, for fluorine-based etchants (including, for example, HF, CF₄, SF₆, CHF₃, C₄F₈, etc.) or fluorine etchant-containing compositions, or chlorine-based etchants (including, for example, HCl, Cl₂, BCl₃, CCl₄) or chlorine etchant-containing compositions).

At least a portion of the adhesive layer 157 may be patterned with apertures or gaps, which are filled in with the conductive material 108. In some embodiments, the apertures in the adhesive layer 157 may have a width between 250 and 750 micrometers, between 250 and 500 micrometers, between 250 and 350 micrometers, or any ranges and sub-ranges therebetween. In some embodiments, the width can be less than 350 micrometers, or less than 300 micrometers, or less than 250 micrometers. In some embodiments, at least a portion of the apertures or gaps of the adhesive layer 157 may be arranged with a pitch, e.g., a minimum pitch between two adjacent apertures, where pitch refers to a center-to-center distance between adjacent apertures. The minimum pitch may be less than 2 millimeters, less than 1 millimeter, or less than 800 micrometers. In some embodiments, the pitch is between 500 micrometers and 1 millimeter, or between 100 micrometers and 500 micrometers, or between 200 micrometers and 1 millimeter, or between 500 micrometers and about 1 millimeter, or between 700 micrometers and 1.5 millimeters, or any ranges and sub-ranges therebetween). In some embodiments, the pitch may be less than or equal to 1 millimeter (for example, between 0.1 and 1 millimeters, or between 0.1 and 0.7 millimeters, or between 0.1 and 0.5 millimeters, or between 0.1 and 0.25 millimeters, or less than or equal to 0.1 millimeters, or any ranges or sub-ranges therebetween). At least a portion of adjacent apertures in the adhesive layer 157 may be arranged at a different pitch, or at multiple different pitches.

The top surface of the support structure 155 may be processed to improve the ability of the support structure 155 to adhere to the adhesive layer 157. For example, the top surface of the support structure 155 may be chemically functionalized such that it can form a strong bond with the adhesive layer 157. In some embodiments, the top surface of the support structure 155 may be coated with a layer of a material that has a higher degree of compatibility or ability to bond with the adhesive layer 157 relative to an uncoated top surface of the support structure 155. In some embodiments, the top surface of the support structure 155 may be chemically or mechanically roughened or otherwise modified to improve the ability of the top surface of the support structure 155 to adhere to the adhesive layer 157.

The support structure material 154 of the support structure 155 may include a glass material, and the support structure 155 is or includes a glass structure. As used herein, the term “glass structure” refers to a layer (e.g., a glass layer) or a structure (e.g., a portion of a glass layer or another article) of any glass material such as quartz, silica, fused silica, silicate glass (e.g., borosilicate, aluminosilicate, aluminoborosilicate, alkali borosilicate, alkali aluminosilicate, alkali aluminoborosilicate, etc.), soda-lime glass, soda-lime silica, borofloat glass, fusion draw glass, chemically strengthened glass (e.g., by ion exchange treatment), lead borate glass, photosensitive glass, non-photosensitive glass, or ceramic glass. In particular, the glass structure may be bulk glass or a solid volume/layer of glass, as opposed to, e.g., materials that may include particles of glass, such as glass fiber-reinforced polymers (e.g., as may be used for substrates/boards constructed of glass fibers and an epoxy binder). Such glass materials are typically non-crystalline, often transparent, amorphous solids. In some embodiments, the glass structure may be an amorphous solid glass layer. In some embodiments, the glass structure may include a material comprising silicon and oxygen, as well as any one or more of aluminum, boron, magnesium, calcium, barium, tin, sodium, potassium, strontium, phosphorus, zirconium, lithium, titanium, and zinc. In some embodiments, the glass structure may include a material, e.g., any of the materials described above, with a weight percentage of silicon being at least about 0.5%, e.g., between about 0.5% and about 50%, between about 1% and about 48%, at least about 23%, or any ranges or sub-ranges therebetween. For example, if the glass structure is fused silica, the weight percentage of silicon may be about 47%. In some embodiments, the glass structure may include a material having at least about 23% silicon and/or at least about 26% oxygen by weight, and, in some further embodiments, the glass structure may further include at least about 5% aluminum by weight. In some embodiments, the glass structure may include any of the materials described above and may further include one or more additives such as Al₂O₃, B₂O₃, MgO, CaO, SrO, BaO, SnO₂, Na₂O, K₂O, SrO, P₂O₃, ZrO₂, Li₂O, Ti, and Zn. In some embodiments, the glass structure may be a layer of glass that does not include an organic adhesive or an organic material. In some embodiments, the support structure material 154 may include a non-glass inorganic material or an organic material.

In some embodiments, the support structure 155 may be a monolithic structure. In some embodiments, the support structure 155 may be formed from multiple structures, or may be formed in layers. In some embodiments, the multiple structures or layers of the support structure 155 may be formed from the same material, or from different materials (e.g., organic and inorganic materials). In some embodiments, multiple support structures 155 (e.g., stacked or side-by-side) may be included.

The support structure 155 may have a relatively low thickness (e.g., a thickness that is less than the thickness of the substrate 107 along the z-axis direction in FIG. 1A). For example, the support structure 155 may have a thickness of less than 1 millimeter in thickness (e.g., between 10 micrometers and 1 millimeter in thickness, or between 20 micrometers and 1 millimeter in thickness, or between 20 micrometers and 500 micrometers in thickness, or between 20 micrometers and 250 micrometers in thickness, or between 20 micrometers and 100 micrometers in thickness, or between 50 and 200 micrometers in thickness, or between 50 and 100 micrometers in thickness, or any ranges and sub-ranges therebetween). The support structure 155 may have a thickness of less than 100% of the thickness of the substrate 107 (e.g., between 1% and 75% of the thickness of the substrate 107, or between 1% and 50% of the thickness of the substrate 107, or between 1% and 25% of the thickness of the substrate 107, or between 1% and 10% of the thickness of the substrate 107, or any ranges and sub-ranges therebetween).

The support structure 155 provides mechanical support for the substrate 107. Specifically, the support structure 155 may increase flexural rigidity of the substrate 107 against package warpage (for example, warpage that might be encountered during manufacturing processes or handling of components of an IC package). In some embodiments, one or more materials used in the support structure 155 may have a Young's modulus of greater than or equal to about 20 GPa (for example, between 20 and 120 GPa, or between 20 and 100 GPa, or between 20 and 80 GPa, or between 20 and 60 GPa, or any ranges and sub-ranges therebetween).

The support structure 155 may include one or more TSSVs 159, e.g., TSSVs 159A and 159B illustrated in FIG. 1A. The TSSVs 159 include the conductive material 108 to provide electrical connections through the support structure 155 (e.g., between conductive material 108 in the substrate 107 and conductive material 108 on the opposite side of the support structure 155, such as to an STPS interconnect 150). The TSSVs 159 extend through a portion of the adhesive layer 157. For example, as noted above, the adhesive layer 157 may be patterned with apertures, and the TSSVs 159 extend through at least a portion of the apertures in the adhesive layer 157. Stated another way, at least a portion of the adhesive layer 157 can be present along a region of the support structure 155 outside of the TSSVs 159. In some embodiments, the TSSVs 159 disclosed herein may have a pitch of less than 2 millimeters, less than 1 millimeter, or less than 800 micrometers. In some embodiments, the pitch is between 500 micrometers and 1 millimeter, or between 100 micrometers and 500 micrometers, or between 200 micrometers and 1 millimeter, or between 500 micrometers and about 1 millimeters, or between 700 micrometers and 1.5 millimeters, or any ranges and sub-ranges therebetween). In some embodiments, the pitch may be less than or equal to 1 millimeter (for example, between 0.1 and 1 millimeters, or between 0.1 and 0.7 millimeters, or between 0.1 and 0.5 millimeters, or between 0.1 and 0.25 millimeters, or less than or equal to 0.1 millimeters, or any ranges or sub-ranges therebetween). At least a portion of adjacent TSSVs 159 may be arranged at a different pitch, or at multiple different pitches.

FIG. 1B is a zoomed view of the side, cross-sectional view of the example microelectronic assembly 100, in accordance with various embodiments. In particular, FIG. 1B is a zoomed view of an area 156 outlined in dotted lines in FIG. 1A. As shown in FIG. 1B, a TSSV 159 may include a first seed layer 166 formed from a seed material 169. The seed material 169 includes a suitable material for growing regions of another material, e.g., copper or another conductive material. In general, a seed layer is a thin initial coating of a material (e.g., a metal, such as copper or another conductive material) that acts as a nucleation site for a subsequent growth process. Various deposition techniques can be used to deposit the seed material 169 of the first seed layer 166, including, e.g., atomic layer deposition (ALD), chemical vapor deposition (CVD), physical vapor deposition (PVD), electroless or electrolytic plating, etc. As shown in FIG. 1B, the first seed layer 166 can be aligned with and deposited over a via 109B of the substrate 107. The via 109B of the substrate 107 may be aligned with an aperture in a patterned portion of the adhesive layer 157. Stated another way, the adhesive material 158 can be present along a region of the support structure 155 outside of the first seed layer 166 (e.g., the portion of the first seed layer 166 that is deposited in the aperture in the patterned portion of the adhesive layer 157).

The TSSV 159 includes a first conductive layer 164 over the first seed layer 166. The first conductive layer includes the conductive material 108, which may be the same conductive material 108 included in the substrate 107, or a different conductive material, e.g., any of the conductive materials described above. The first conductive layer 164 is formed (e.g., deposited or plated) over the first seed layer 166. For example, the first conductive layer 164 (e.g., copper or another metal) may be grown over the first seed layer 166 using an electroless deposition or electroplating process. If the seed material 169 of the first seed layer 166 is different from the conductive material 108 in the first conductive layer 164 (e.g., if a palladium seed is used for copper growth), the first seed layer 166 may be evident at the base of the first conductive layer 164, e.g., as a liner.

The TSSV 159 further includes a filler 163. The filler 163 is in contact with, and may be surrounded by and/or enclosed in, the first conductive layer 164. The filler 163 includes a filler material 162, which may be a dielectric material. The dielectric material may include a ceramic, an epoxy resin (for example, an epoxy film with filler particles therein), or glass. The dielectric material may include an inorganic material, an organic material, or combinations of organic and inorganic materials. The filler material 162 may include the same or a similar material to the dielectric material 112 of the substrate 107, and/or the dielectric material of the filler material 162 may include a different material. The filler material 162 may have a CTE substantially similar to the support structure material 154, similar to the first conductive layer 164, or intermediate between the CTEs of the support structure material 154 and the first conductive layer 164. In some embodiments, the filler material 162 may have a CTE that is different from a CTE of the support structure material 154 or the first conductive layer 164. In some embodiments, the CTE of the filler material 162 may be between 1 and 20 parts per million (ppm) per degree Celsius (C.) (for example, between 1 and 15 ppm/C, or between 1 and 10 ppm/C, or between 2 and 15 ppm/C, or between 3 and 12 ppm/C, or between 5 and 10 ppm/C, or any ranges or sub-ranges therebetween).

In this example, the TSSV 159 includes a second seed layer 168 and a second conductive layer 144 formed over the second seed layer 168 (and positioned under the second seed layer 168 in the orientation shown). The second seed layer 168 and second conductive layer 144 may jointly form a conductive cap 174 for the TSSV 159. The conductive cap 174, and in particular, the second seed layer 168, is in physical and/or electrical contact with the first seed layer 166, the first conductive layer 164, and the filler 163. In this example, the filler 163 is surrounded by (e.g., enclosed in) conductive materials of the TSSV 159; in this case, the filler 163 is directly surrounded by the first conductive layer 164 and the second seed layer 168. Similar to the first seed layer 166, the second seed layer 168 may include a thin initial coating of a material (e.g., a metal, such as copper or another conductive material) that acts as a nucleation site for a subsequent growth process. Various deposition techniques can be used to deposit the second seed layer 168 over the first seed layer 166, the first conductive layer 164, and the filler 163, including, e.g., ALD, CVD, PVD, etc. In some embodiments, the second seed layer 168 may include the same material or a similar material as the first seed layer 166 (e.g., the seed material 169), and/or the second seed layer 168 may include different materials.

The second conductive layer 144 is formed (e.g., deposited or plated) over the second seed layer 168. For example, the second conductive layer 144 (e.g., copper or another metal) may be grown over the second seed layer 168 using an electroless deposition or electroplating process. If the second seed layer 168 includes a different material from the second conductive layer 144 (e.g., a palladium seed for copper growth), the second seed layer 168 may be evident at the base of the grown second conductive layer 144, e.g., as a liner material. In some embodiments, the second conductive layer 144 may comprise a conductive material that is the same as or similar to the conductive material 108 of the first conductive layer 164 (or the same as or similar to the conductive material 108 included in the substrate 107), and/or different materials may be included in the second conductive layer 144.

As shown in FIG. 1B, the TSSV 159 can have a frustoconical shape. However, in other embodiments, other shapes are contemplated. For example, the TSSV 159 may have a frustopyramidal shape, a smooth or stepped funnel shape, a bell-like shape, etc. In the example shown in FIG. 1, a first width 170 of a top end of the TSSV 159 (e.g., an end of the TSSV 159 closer to the substrate 107 than an opposing end of the TSSV 159) is less than a second width 172 of a bottom end of the TSSV 159 (e.g., an end of the TSSV 159 further away from the substrate 107 than an opposing end of the TSSV 159).

For example, the first width 170 of the top end of the TSSV 159 may be between 100 and 750 micrometers, or between 250 and 750 micrometers, or between 250 and 500 micrometers, or between 250 and 350 micrometers, or any ranges and sub-ranges therebetween. In some embodiments, the first width 170 can be less than 350 micrometers, or less than 300 micrometers, or less than 250 micrometers, or less than or equal to 100 micrometers. The second width 172 of the bottom end of the TSSV 159 can be between 100 and 850 micrometers, or between 350 and 600 micrometers, or between 350 and 450 micrometers, or any ranges or sub-ranges therebetween. The second width 172 can be greater than or equal to 100 micrometers, or greater than or equal to 250 micrometers, or greater than or equal to 300 micrometers, or greater than or equal to 350 micrometers. The first width 170 may be between 20% and 95% of the second width 172, or between 30% and 85% of the second width 172, or between 40% and 75% of the second width 172, or between 50% and 65% of the second width 172, or any ranges or sub-ranges therebetween. In other embodiments, the first width 170 may be the same or greater than the second width 172.

Returning to FIG. 1A, the support structure 155 may be coupled to the package substrate 102. In particular, the top surface of the package substrate 102 may include a set of conductive contacts 146. The conductive contacts 146 may comprise a conductive material that is the same as or similar to the conductive material 108 in the substrate 107, and/or may comprise a different conductive material. Conductive contacts (e.g., the conductive layer 144) of the TSSVs 159 may be physically and electrically coupled to the conductive contacts 146 on the top surface of the package substrate 102 by the STPS interconnects 150. The package substrate 102 may include an insulating material (e.g., a dielectric material formed in multiple layers, as known in the art) and one or more conductive pathways to route power, ground, and signals through the insulating material (e.g., including conductive traces and/or conductive vias). In some embodiments, the insulating material of the package substrate 102 may be a dielectric material, such as an organic dielectric material, a fire-retardant grade 4 material (FR-4), BT resin, polyimide materials, glass reinforced epoxy matrix materials, organic dielectrics with inorganic fillers or low-k and ultra-low-k dielectric (e.g., carbon-doped dielectrics, fluorine-doped dielectrics, porous dielectrics, and organic polymeric dielectrics). In particular, when the package substrate 102 is formed using standard PCB processes, the package substrate 102 may include FR-4, and the conductive pathways in the package substrate 102 may be formed by patterned sheets of copper separated by build-up layers of the FR-4. The conductive pathways in the package substrate 102 may be bordered by liner materials, such as adhesion liners and/or barrier liners, as suitable. In some embodiments, the package substrate 102 may be formed using a lithographically defined via packaging process. In some embodiments, the package substrate 102 may be manufactured using standard organic package manufacturing processes, and thus the package substrate 102 may take the form of an organic package. In some embodiments, the package substrate 102 may be a set of redistribution layers formed on a panel carrier by laminating or spinning on a dielectric material, and creating conductive vias and lines by laser drilling and plating. In some embodiments, the package substrate 102 may be formed on a removable carrier using any suitable technique, such as a redistribution layer technique. Any method known in the art for fabrication of the package substrate 102 may be used, and for the sake of brevity, such methods will not be discussed in further detail herein.

In some embodiments, the package substrate 102 may be a lower density medium and the die 114 (e.g., any one or more of the dies 114-1, 114-2, 114-3) may be a higher density medium or have an area with a higher density medium. As used herein, the term “lower density” and “higher density” are relative terms indicating that the conductive pathways (e.g., including conductive interconnects, conductive lines, and conductive vias) in a lower density medium are larger and/or have a greater pitch than the conductive pathways in a higher density medium. In some embodiments, a higher density medium may be manufactured using a modified semi-additive process or a semi-additive build-up process with advanced lithography (with small vertical interconnect features formed by advanced laser or lithography processes), while a lower density medium may be a PCB manufactured using a standard PCB process (e.g., a standard subtractive process using etch chemistry to remove areas of unwanted copper, and with coarse vertical interconnect features formed by a standard laser process). In other embodiments, the higher density medium may be manufactured using a semiconductor fabrication process, such as a single damascene process or a dual damascene process. In some embodiments, additional dies may be disposed on one or more top surfaces of the dies 114-2, 114-3. In some embodiments, additional components may be disposed on one or more of the top surface of the dies 114-2, 114-3. Additional passive components, such as surface mount resistors, capacitors, and/or inductors, may be disposed on a surface (e.g., the top surface or the bottom surface) of the package substrate 102, or embedded in the package substrate 102.

The microelectronic assembly 100 of FIG. 1 may also include an additional layer 161. The additional layer 161 may be over a side of the support structure 155 opposite the adhesive layer 157. As shown in FIG. 1, the additional layer 161 is between the support structure 155 and the package substrate 102 (e.g., at the bottom of the support structure 155). In some embodiments, the additional layer 161 may include a dielectric material 160. The dielectric material 160 may include a solder resist or solder mask. In some embodiments, the dielectric material 160 may include a resin material. The resin material may include an epoxy resin, a silicone resin, an acrylate resin (e.g., urethane acrylate), or another type of resin.

At least a portion of the additional layer 161 may be patterned with apertures or gaps in the additional layer 161. In some embodiments, at least a portion of the apertures of the additional layer 161 may be arranged with a pitch, e.g., a minimum pitch between two adjacent apertures. The pitch may be less than 2 millimeters, less than 1 millimeter, or less than 800 micrometers. In some embodiments, the pitch is between 500 micrometers and 1 millimeter, or between 100 micrometers and 500 micrometers, or between 200 micrometers and 1 millimeter, or between 500 micrometers and about 1 millimeters, or between 700 micrometers and 1.5 millimeters, or any ranges and sub-ranges therebetween). At least a portion of adjacent apertures in the additional layer 161 may be arranged at a different pitch, or at multiple different pitches.

In some embodiments, at least a portion of the apertures in the additional layer 161 may be at least partially filled with a conductive material (e.g., the conductive material 108). As shown in FIG. 1, the TSSVs 159 (e.g., the conductive caps 174 of the TSSVs 159) extend through apertures of the additional layer 161. Stated in a different way, the dielectric material 160 can be present along a region of the support structure 155 outside of the TSSVs 159 (e.g., the second seed layer 168 and the second conductive layer or conductive contact 144).

The microelectronic assembly 100 of FIG. 1 may also include an underfill layer 128 comprising an underfill material 127. In some embodiments, the underfill layer 128 may extend between the substrate 107 and the package substrate 102 around the associated STPS interconnects 150. In particular, the underfill layer 128 may extend between the additional layer 161 and the package substrate 102 around the associated STPS interconnects 150. In some embodiments, an underfill layer 141 (e.g., comprising the same underfill material 127 and/or a different underfill material) may extend between the dies 114-2, 114-3 (e.g., top level dies) and the top surface of the substrate 107 around the associated DTS interconnects 140 and/or between the bridge die 114-1 and the top level dies 114-2, 114-3 around the associated DTD interconnects 130. In some embodiments, an underfill layer 115 (e.g., comprising the same underfill material 127 or a different underfill material) may extend between the bridge die 114-1 and the substrate 107 around the BTS interconnects 151. The underfill material 127 may include an insulating material, such as an appropriate epoxy material. In some embodiments, the underfill material 127 may include a capillary underfill, non-conductive film (NCF), or molded underfill. In some embodiments, the underfill material 127 may include an epoxy flux that assists with soldering the conductive contact of the TSSV 159 (e.g., the second conductive layer 144 of the conductive cap 174) to conductive contacts 146 of the package substrate 102 when forming the STPS interconnects 150, and then polymerizes and encapsulates the STPS interconnects 150. The underfill material 127 may be selected to have a CTE that may mitigate or minimize the stress between the substrate 107 and the package substrate 102 (or between the additional layer 161 and the package substrate 102) arising from uneven thermal expansion in the microelectronic assembly 100. In some embodiments, the CTE of the underfill material 127 may have a value that is intermediate to the CTE of the package substrate 102 (e.g., the CTE of the dielectric material of the package substrate 102) and a CTE of the dies 114 and/or dielectric material 112 of the substrate 107.

The STPS interconnects 150 disclosed herein may take any suitable form. The STPS interconnects 150 may comprise the same conductive material 129 as the DTD interconnects 130, and/or may comprise a different conductive material. In some embodiments, a set of STPS interconnects 150 may include solder (e.g., solder bumps or balls that are subject to a thermal reflow to form the STPS interconnects 150). For example, as shown in FIG. 1, the STPS interconnects 150 may include solder between the conductive contact of the TSSV 159 (e.g., the second conductive layer 144 of the conductive cap 174) and the conductive contact 146 on the top surface of the package substrate 102. In some embodiments, a set of STPS interconnects 150 may include an anisotropic conductive material, such as an anisotropic conductive film or an anisotropic conductive paste. An anisotropic conductive material may include conductive materials dispersed in a non-conductive material.

Similarly, the BTS interconnects 151 disclosed herein may take any suitable form. The BTS interconnects 151 may comprise the same conductive material 129 as the DTD interconnects 130 or the STPS interconnects 150, and/or may comprise a different conductive material. In some embodiments, a set of BTS interconnects 151 may include solder (e.g., solder bumps or balls that are subject to a thermal reflow to form the BTS interconnects 151). For example, as shown in FIG. 1, the BTS interconnects 151 may include solder between conductive contacts 122 on the bottom surface of the bridge die 114-1 and a conductive contact 109A in the substrate 107. In some embodiments, a set of BTS interconnects 151 may include an anisotropic conductive material, such as an anisotropic conductive film or an anisotropic conductive paste. An anisotropic conductive material may include conductive materials dispersed in a non-conductive material.

The DTD interconnects 130 disclosed herein may take any suitable form. As noted earlier, the DTD interconnects 130 may comprise a conductive material 129. The DTD interconnects 130 may have a finer pitch than the STPS interconnects 150 in the microelectronic assembly 100. In some embodiments, the dies 114 on either side of a set of DTD interconnects 130 may be unpackaged dies, and/or the DTD interconnects 130 may include small conductive bumps (e.g., copper bumps). The DTD interconnects 130 may have too fine a pitch to couple to the package substrate 102 directly (e.g., too fine to serve as DTS interconnects 140 or STPS interconnects 150). In some embodiments, a set of DTD interconnects 130 may include solder. In some embodiments, a set of DTD interconnects 130 may include an anisotropic conductive material. In some embodiments, a set of DTD interconnects 130 may include any of the materials discussed above for the BTS interconnects 151, the STPS interconnects 150, or the DTS interconnects 140. In some embodiments, the DTD interconnects 130 may be used for data transfer lines, while the STPS interconnects 150 may be used for power and ground lines, among others. In some embodiments, some or all of the DTD interconnects 130 in the microelectronic assembly 100 may be metal-to-metal interconnects (e.g., copper-to-copper interconnects, or plated interconnects). In such embodiments, the DTD interconnect 130 may be bonded (e.g., to conductive vias 109B and conductive contacts 122 on the bottom surfaces of dies 114-2, 114-3) under elevated pressure and/or temperature, without the use of intervening solder or an anisotropic conductive material. Any of the conductive contacts disclosed herein (e.g., the conductive contacts 122, 124, 144, and/or 146) may include bond pads, solder bumps, conductive posts, or any other suitable conductive contact, for example. In some embodiments, some or all of the DTD interconnects 130, the DTS interconnects 140, and/or the BTS interconnects 151 in a microelectronic assembly 100 may be solder interconnects that include a solder with a higher melting point than a solder included in some or all of the STPS interconnects 150. For example, when the DTD interconnects 130, the DTS interconnects 140, and the BTS interconnects 151 in a microelectronic assembly 100 are formed before the STPS interconnects 150 are formed, solder-based DTD interconnects 130, DTS interconnects 140, and BTS interconnects 151 may use a higher-temperature solder (e.g., with a melting point above 200 degrees Celsius), while the STPS interconnects 150 may use a lower-temperature solder (e.g., with a melting point below 200 degrees Celsius). In some embodiments, a higher-temperature solder may include tin; tin and gold; or tin, silver, and copper (e.g., 96.5% tin, 3% silver, and 0.5% copper). In some embodiments, a lower-temperature solder may include tin and bismuth (e.g., eutectic tin bismuth) or tin, silver, and bismuth. In some embodiments, a lower-temperature solder may include indium, indium and tin, or gallium.

In the microelectronic assemblies 100 disclosed herein, some or all of the DTS interconnects 140 and the STPS interconnects 150 may have a larger pitch than some or all of the DTD interconnects 130. DTD interconnects 130 may have a smaller pitch than STPS interconnects 150 or the DTS interconnects 140 due to the greater similarity of materials in the different dies 114 on either side of a set of DTD interconnects 130 than between the substrate 107 and the top level dies 114-2, 114-3 on either side of a set of DTS interconnects 140, and between the TSSV 159 and the package substrate 102 on either side of a set of STPS interconnects 150. In particular, the differences in the material composition of a substrate 107 and a die 114 or a package substrate 102 may result in differential expansion and contraction due to heat generated during operation (as well as the heat applied during various manufacturing operations). To mitigate damage caused by this differential expansion and contraction (e.g., cracking, solder bridging, etc.), the DTS interconnects 140 and the STPS interconnects 150 may be formed larger and farther apart than DTD interconnects 130, which may experience less thermal stress due to the greater material similarity of the pair of dies 114 on either side of the DTD interconnects 130. In some embodiments, the DTS interconnects 140 disclosed herein may have a pitch between 25 micrometers and 250 micrometers, or any ranges or sub-ranges therebetween. In some embodiments, the STPS interconnects 150 disclosed herein may have a pitch between 55 micrometers and 1000 micrometers, or any ranges or sub-ranges therebetween, while the DTD interconnects 130 disclosed herein may have a pitch between 25 micrometers and 100 micrometers, or any ranges or sub-ranges therebetween.

The microelectronic assembly 100 of FIG. 1 may also include a circuit board (not shown). The package substrate 102 may be coupled to the circuit board by second-level interconnects at the bottom surface of the package substrate 102. The second-level interconnects may be any suitable second-level interconnects, including solder balls for a ball grid array arrangement, pins in a pin grid array arrangement or lands in a land grid array arrangement. The circuit board may be a motherboard, for example, and may have other components attached to it. The circuit board may include conductive pathways and other conductive contacts for routing power, ground, and signals through the circuit board, as known in the art. In some embodiments, the second-level interconnects may not couple the package substrate 102 to a circuit board, but may instead couple the package substrate 102 to another IC package, an interposer, or any other suitable component. In some embodiments, the substrate 107 may not be coupled to a package substrate 102 (e.g., through the TSSVs 159 and STPS interconnects 150), but may instead be coupled to a circuit board, such as a PCB.

Although FIG. 1 depicts a microelectronic assembly 100 having a particular number of dies 114 and conductive material 108 (e.g., conductive pathways) coupled to other dies 114, this number and arrangement are simply illustrative, and a microelectronic assembly 100 may include any desired number and arrangement of dies 114. Although FIG. 1 shows the bridge die 114-1 as a double-sided die and the dies 114-2, 114-3 as single-sided dies, the dies 114-2, 114-3 may be double-sided dies. The dies 114 may be single-pitch dies or mixed-pitch dies. In some embodiments, additional components may be disposed on the top surfaces of the dies 114-2 and/or 114-3. In this context, a double-sided die refers to a die that has connections on both surfaces. In some embodiments, a double-sided die may include vias (e.g., through silicon vias or TSVs) to form connections on both surfaces. An active surface of a double-sided die, which is a surface containing one or more active devices and a majority of interconnects, if present, may face any direction depending on the design and electrical requirements.

Many of the elements of the microelectronic assembly 100 of FIG. 1 are included in other ones of the accompanying drawings; the discussion of these elements is not repeated when discussing these drawings, and any of these elements may take any of the forms disclosed herein. Further, a number of elements are illustrated in FIG. 1 as included in the microelectronic assembly 100, but a number of these elements may not be present in a microelectronic assembly 100. For example, in various embodiments, the additional layer 161, one or more intermediary layers (e.g., including the adhesive layer 157), the underfill layers 115, 128, and/or 141, and/or the package substrate 102 may not be included. In some embodiments, individual ones of the microelectronic assemblies 100 disclosed herein may serve as a system-in-package (SiP) in which multiple dies 114 having different functionality are included. In such embodiments, the microelectronic assembly 100 may be referred to as an SiP.

FIG. 2 illustrates one example process 200 that may be used to manufacture the microelectronic assembly 100. FIGS. 3A-3T are side, cross-sectional views of various stages in the example process 200. FIGS. 4A-4D are zoomed views of portions of the side, cross-sectional view of FIG. 3T. Although the operations discussed below with reference to FIGS. 2-4 (and others of the accompanying drawings representing manufacturing processes) are illustrated in a particular order, these operations may be performed in any suitable order. Further, additional operations which are not illustrated may also be performed without departing from the scope of the present disclosure. Also, various ones of the operations discussed herein with respect to FIGS. 2-4 may be modified in accordance with the present disclosure to fabricate others of microelectronic assembly 100 disclosed herein.

At 205 of FIG. 2, a carrier joined to a first preliminary substrate (e.g., a portion of the substrate 107) and a second preliminary substrate (e.g., a similar portion of the substrate 107) is provided. FIG. 3A illustrates an assembly that includes a carrier 302 and two preliminary substrates 301 (e.g., preliminary substrates 301A and 301B). The carrier 302 includes a carrier material 303, which may be any suitable material for providing mechanical stability during manufacturing operations, such as a glass and/or a resin. The first preliminary substrate 301A (e.g., a front side preliminary substrate) is on one side of the carrier 302, and the second preliminary substrate 301B (e.g., a back side preliminary substrate) is on the second side of the carrier 302. The preliminary substrates 301A and 301B generally correspond to the dielectric material layer 113A of the substrate 107 shown in FIG. 1. The preliminary substrates 301A and 301B include a dielectric material 307, which may be the same as the dielectric material 112 of the substrate 107 shown in FIG. 1. The preliminary substrates 301A and 301B further include conductive features corresponding to the lines/traces/pads/contacts 109A and vias 109B of the substrate 107 shown in FIG. 1 and formed from a conductive material 309. The conductive material 309 may be the same as the conductive material 108 of FIG. 1. The conductive features in the preliminary substrates 301A and 301B may include at least the N-2, N-3, and N-4 layers shown in FIG. 1. Each of the first preliminary substrate 301A and second preliminary substrate 301B may be joined to the carrier 302 by a first interstitial layer 304A and second interstitial layer 304B, respectively. The interstitial layers 304A, 304B include an interstitial material 305, which may include a conductive material, such as a copper foil. In some embodiments, the interstitial material 305 may include an adhesive.

The preliminary substrates 301A and 301B of FIG. 3A may be manufactured using conventional package substrate manufacturing techniques (e.g., lamination of layers of dielectric material 307, deposition of conductive materials 309 on or in the dielectric material 307, etc.). The preliminary substrates 301A and 301B may be at least partially manufactured over the carrier 302 (e.g., over the first and/or second interstitial layers 304A, 304B), or may be joined to the carrier 302 (e.g., to the first and/or second interstitial layers 304A, 304B) by any suitable means or process. Surfaces of the first and second preliminary substrates 301A, 301B (e.g., surfaces facing away from the carrier 302 and/or the interstitial layers 304A, 304B) may be planarized using chemical-mechanical polishing (CMP) or any other suitable process. The first and/or second interstitial layers 304A, 304B may be joined to the carrier 302 by any suitable means or process. For example, one or more adhesives may be used to bond the first and/or second interstitial layers 304A, 304B to the carrier 302, or some other means may be used to form a physical or chemical (e.g., ionic, covalent, hydrogen, or metallic) bond between the first and/or second interstitial layers 304A, 304B and the carrier 302.

As shown in FIG. 3A, pads of conductive material 309 are exposed at surfaces of the first and second preliminary substrates 301A, 301B, and the pads may project outwardly from the surfaces (e.g., as shown in FIG. 3A, from a top surface of the first preliminary substrate 301A and from a bottom surface of the second preliminary substrate 301B). In some embodiments, at least some of the pads may not be present, and ends of vias of the conductive material 309 may be flush with the surfaces of the first and/or second preliminary substrates 301A, 301B.

At 210, a first adhesive layer is placed over an exposed surface of the first preliminary substrate (including over the exposed pads of conductive material 309 noted above). FIG. 3B illustrates the assembly of FIG. 3A after placing a first adhesive layer 310A over the exposed surface of the first preliminary substrate 301A (i.e., the top surface of the first preliminary substrate 301A). The first adhesive layer 310A includes an adhesive material 311, which may be the same as the adhesive material 158 of FIG. 1. The first adhesive layer 310A may be placed over the top surface of the first preliminary substrate 301A by any suitable technique. For example, the first adhesive layer 310A may be deposited by a contact coating method and/or a non-contact coating method. Contact coating methods may include, e.g., flexography, roll coating, blade coating, and/or gravure roll coating. Non-contact coating methods may include, e.g., spraying, printing, and/or jetting.

At 215 of FIG. 2, a first preliminary support structure is placed over the first adhesive layer. The first preliminary support structure can include first cavities that had been previously formed therein. FIG. 3C illustrates the assembly of FIG. 3B after placing a first preliminary support structure 312A over the first adhesive layer 310A. The first preliminary support structure 312A includes first cavities 314A-1, 314A-2, 314A-3, 314A-4 (collectively first cavities 314A). The first preliminary support structure 312A can include a support structure material 313, which may be the same as the support structure material 154 of the support structure 155 shown in FIG. 1 (e.g., a glass material). The bottom surface of the first preliminary support structure 312A may be processed to improve the ability of the first preliminary support structure 312A to adhere to the first adhesive layer 310A. The manner in which the first preliminary support structure 312A may be processed may be the same as or similar to the manner described earlier in which the top surface of the support structure 155 may be processed to improve the ability of the support structure 155 to adhere to the adhesive layer 157.

Although four first cavities 314A (e.g., 314A-1, 314A-2, 314A-3, 314A-4) in the first preliminary support structure 312A are illustrated, the numbers and arrangements of the first cavities 314A are simply illustrative, and any desired number and arrangement of first cavities 314A may be present. The size and pitches of the first cavities 314A may be the same as described with respect to the TSSVs 159 of FIG. 1. The first cavities 314A may be formed in the first preliminary support structure 312A by any suitable technique. For example, the first cavities 314A may be formed by mechanically drilling, mechanically cutting, laser ablating, or chemically etching the first preliminary support structure 312A, and/or otherwise removing a portion of the first preliminary support structure 312A. The shapes of the first cavities 314A may be any suitable shape, e.g., the shapes described with respect to the TSSVs 159.

At 220 of FIG. 2, a second adhesive layer is placed over an exposed surface of the second preliminary substrate. At 225 of FIG. 2, a second preliminary support structure is placed over the second adhesive layer. The second preliminary support structure can include second cavities that had been previously formed therein. FIG. 3D illustrates the assembly of FIG. 3C after placing a second adhesive layer 310B over a surface of the second preliminary substrate 301B (e.g., the bottom surface of the second preliminary substrate 301B). The second adhesive layer 310B may include the same adhesive material or a similar adhesive material as the adhesive material 311 of the first adhesive layer 310A, and the second adhesive layer 310B may be placed over the bottom surface of the second preliminary substrate 301B by any suitable technique, including by the coating methods described above for placing the first adhesive layer 310A over the top surface of the first preliminary substrate 301A. FIG. 3D further illustrates the assembly after placing a second preliminary support structure 312B over the second adhesive layer 310B. The second preliminary support structure 312B includes second cavities 314B-1, 314B-2, 314B-3, 314B-4 (collectively second cavities 314B). The second preliminary support structure 312B can include the same support structure material 313 as the first preliminary support structure 312A. Furthermore, the second preliminary support structure 312B may be processed to improve the ability of the second preliminary support structure 312B to adhere to the second adhesive layer 310B in the same or a similar manner to the processing described above for the first preliminary support structure 312A to improve the ability of the first preliminary support structure 312A to adhere to the first adhesive layer 310A. The number, arrangement, pitch, formation, and shape of second cavities 314B of the second preliminary support structure 312B may be the same or similar to that described above with respect to the number, arrangement, pitch, formation, and shape of first cavities 314A of the first preliminary support structure 312A.

In some embodiments, the assembly of FIG. 3D may be cut or trimmed to a desired set of dimensions (e.g., length or width) in accordance with customer requirements or requirements for further processing. The assembly may be cut or trimmed using any suitable process. For example, the assembly may be cut using a mechanical cutting tool (e.g., a blade, a scoring knife, and/or a scoring wheel), a laser cutting tool (e.g., a CO₂ laser, a fiber laser, a yttrium-aluminum-garnet (YAG) or yttrium ortho vanadate (YVO) laser (e.g., Nd:YAG or Nd:YVO laser), and/or a direct diode laser), a thermal cutting tool (e.g., heating and/or chilling tools for propagating imparted initiation marks or flaws to achieve a desired cut or break), a fluid cutting tool (e.g., a gas or fluid jetting tool), an etchant, and/or another cutting means.

The order in which the first and second adhesive layers 310A, 310B and first and second preliminary support structures 312A, 312B may be placed may vary. For example, in some embodiments, the first adhesive layer 310A may be placed over an exposed surface of the first preliminary substrate 301A, and then the first preliminary support structure 312A may be placed over the first adhesive layer 310A before placing the second adhesive layer 310B over an exposed surface of the second preliminary substrate 301B and placing the second preliminary support structure 312B over the second adhesive layer 310B. In some embodiments, the second adhesive layer 310B may be placed over the exposed surface of the second preliminary substrate 301B, the second preliminary support structure 312B may be placed over the second adhesive layer 310B, the first adhesive layer 310A may be placed over the exposed surface of the first preliminary substrate 301A, and the first preliminary support structure 312A may be placed over the first adhesive layer 310A. In some embodiments, the first and second adhesive layers 310A, 310B may be placed over exposed surfaces of the first and second preliminary substrates 301A, 301B before placing the first and second preliminary support structures 312A, 312B over the first and second adhesive layers 310A, 310B. In some embodiments, the first adhesive layer 310A and the second adhesive layer 310B may be placed over the exposed surface of the first preliminary substrate 301A and the exposed surface of the second preliminary substrate 301B at different times, or substantially simultaneously. In some embodiments, the first preliminary support structure 312A and the second preliminary support structure 312B may be placed over the first adhesive layer 310A and the second adhesive layer 310B at different times, or substantially simultaneously.

At 230 of FIG. 2, the first preliminary substrate and the second preliminary substrate (and the first interstitial layer and second interstitial layer) are separated from the carrier. FIG. 3E illustrates a portion of the assembly of FIG. 3D after separating the first preliminary substrate 301A from the carrier 302. As shown in FIG. 3E, the remaining portion of the assembly includes the second preliminary substrate 301B, second interstitial layer 304B, second adhesive layer 310B, and second preliminary support structure 312B. The carrier 302 may be separated from the second interstitial layer 304B by any suitable technique. For example, the carrier 302 may be separated (e.g., peeled, debonded, or delaminated) from the second interstitial layer 304B by using a blade, an adhesive pad or roller tool, and/or one or more vacuum or suction tools to force apart the carrier 302 and the second interstitial layer 304B, using a laser or an etchant to physically or chemically modify or destroy a bond or interface between the carrier 302 and the second interstitial layer 304B, and/or another separation method. The carrier 302 may be separated from the first interstitial layer 304A in the same or a similar manner. The carrier 302 may be discarded, or may be reused after the separation.

For ease of discussion, further processes of FIG. 2 and further stages in FIG. 3 are described only with reference to the assembly illustrated in FIG. 3E (e.g., the second preliminary substrate 301B, the second preliminary support structure 312B, etc.), and not with reference to the first preliminary substrate 301A, the first preliminary support structure 312A, etc. However, further processes of FIG. 2 and further stages in FIG. 3 may be similarly practiced on the upper assembly of FIG. 3D to manufacture a similar microelectronic assembly. Advantageously, forming at least portions of multiple microelectronic assemblies over both sides of the carrier 302 can allow for a balanced distribution of stresses between multiple microelectronic assemblies during their formations, leading to lessened risk of warp or other manufacturing complications.

At 235 of FIG. 2, a portion of the second adhesive layer over the second preliminary substrate is removed along the ends of the second cavities in the second preliminary support structure. FIG. 3F illustrates the assembly of FIG. 3E after removing a portion of the second adhesive layer 310B at the second cavities 314B. The removal of a portion of the second adhesive layer 310B may cause the second adhesive layer 310B to be patterned with apertures or gaps. Widths or pitches of the apertures of the second adhesive layer 310B may be the same or similar to those described earlier for the adhesive layer 157 shown in FIG. 1. At least a portion of the second cavities 314B in the second preliminary support structure 312B are aligned with conductive features in the second preliminary substrate 301B, so that removing the portions of the second adhesive layer 310B at the cavities 314B exposes the ends of the conductive features. The portion of the second adhesive layer 310B may be removed by any suitable technique. For example, in some embodiments, the portion of the second adhesive layer 310B may be removed using a wet etching process, a dry etching process (e.g., reactive-ion etching, plasma etching, or another ion-bombardment type etching process), a solvent, and/or a mechanical removal process (e.g., using a blowing tool, a scraping tool, a grinding tool, a wiping tool, etc.).

At 240 of FIG. 2, a first seed layer is deposited over the second preliminary support structure. FIG. 3G illustrates the assembly of FIG. 3F after depositing a first seed layer 316 over the second preliminary support structure 312B. The first seed layer 316 includes a seed material 317, which may be the same as the seed material 169 of the first seed layer 166 shown in FIG. 1 (e.g., copper or another conductive material). The first seed layer 316 may be deposited over the second preliminary support structure 312B in the same or a similar manner to the manner described above in which the first seed layer 166 is deposited. As shown in FIG. 3G, the first seed layer 316 is deposited over one or more walls of the second preliminary support structure 312B, including walls defining the second cavities 314B. Furthermore, the first seed layer 316 can be aligned with and deposited over conductive features (e.g., vias 308B) of the second preliminary substrate 301B that were exposed by removing areas of the adhesive material 311.

At 245 of FIG. 2, a first conductive layer is deposited over the first seed layer. FIG. 3H illustrates the assembly of FIG. 3G after depositing a first conductive layer 318 over the first seed layer 316. The first conductive layer 318 is formed from the conductive material 309, i.e., the same conductive material that is in the second preliminary substrate 301B; alternatively, a different conductive material may be used. The first conductive layer 318 may be deposited in the same or a similar manner to the first conductive layer 164 described with respect to FIG. 1 (e.g., by an electroless deposition or electroplating process).

At 250 of FIG. 2, a filler layer is deposited over the first conductive layer. FIG. 3I illustrates the assembly of FIG. 3H after depositing a filler layer 320 over the first conductive layer 318. The filler layer 320 may include a filler material 321. The filler material 321 may be the same or similar to the filler material 162 described above with reference to FIG. 1 (e.g., including a dielectric material, a resin, and/or another material), and deposited using the techniques described above. The filler layer 320 may be deposited over the first conductive layer 318 using any suitable technique. For example, in some embodiments, the filler layer 320 may be molded over the first conductive layer 318 using a molding process (e.g., a plastics molding process such as injection molding). In some embodiments, a contact coating method (e.g., flexography, roll coating, blade coating, and/or gravure roll coating) or a non-contact coating method (e.g., spraying, printing, and/or jetting) may be employed to deposit the filler layer 320 over the first conductive layer 318. In some embodiments, the filler material 321 of the filler layer 320 may include a curable material (e.g., a UV-curable epoxy material) that may be cured after the filler layer 320 is deposited over the first conductive layer 318. After deposition of the filler layer 320 over the first conductive layer 318, the filler material 321 may substantially fill a remainder of space in second cavities 314B in the second preliminary support structure 312B, causing the second cavities 314B to be filled. The second cavities 314B may be referred to hereinafter as filled cavities 324 as outlined in dashed lines in FIG. 3I.

At 255, material is removed from the second preliminary support structure to expose the face of the second preliminary support structure and the ends of the second filled cavities. FIG. 3J illustrates the assembly of FIG. 3I after removing material from the second preliminary support structure 312B, exposing the lower face of the second preliminary support structure 312B and the lower ends of the filled cavities 324. In particular, as shown, a portion of the filler layer 320, a portion of the first conductive layer 318, and a portion of the first seed layer 316 may be removed from a side or surface of the second preliminary support structure 312B (e.g., the bottom side of the second preliminary support structure 312B). A portion of the filler layer 320, a portion of the first conductive layer 318, and a portion of the first seed layer 316, which may collectively be referred to as the excess material, may be removed such that the remaining portions of the filler layer 320, first conductive layer 318, and first seed layer 316 may be substantially only in the filled cavities 324 in the second preliminary support structure 312B. The excess material may be removed by any suitable technique. For example, in some embodiments, a mechanical removal process or tool may be used to remove the excess material (e.g., a grinding tool or process, a polishing tool or process, a scraping tool or process, and/or a cutting tool or process). In some embodiments, the excess material may be removed using an etching process (e.g., a wet etching process and/or a dry etching process). In some embodiments, the bottom side of the second preliminary support structure 312B may be planarized using CMP or any other suitable process. After removal of the excess material, cleaning, and/or planarization, the ends of the filled cavities 324 may be substantially level or flush with the bottom side or face of the second preliminary support structure 312B.

At 260, a second seed layer is deposited over the second preliminary support structure. FIG. 3K illustrates the assembly of FIG. 3J after depositing a second seed layer 322 over the second preliminary support structure 312B (e.g., the bottom side or face of the second preliminary support structure 312B). As shown, the second seed layer 322 is deposited over the support structure material 313 of the second preliminary support structure 312B. The second seed layer 322 is also deposited over the filled cavities 324. The second seed layer 322 may comprise the same material or a similar material to the seed material 317 of the first seed layer 316 as described above (e.g., copper or another conductive material). The second seed layer 322 may be deposited in the same manner or a similar manner to the manner described above in which the first seed layer 316 is deposited over the second preliminary support structure 312B (e.g., ALD, CVD, PVD, electroless or electrolytic plating).

At 265, a shield material is deposited over the second seed layer. FIG. 3L illustrates the assembly of FIG. 3K after depositing a shield material 325 over the second seed layer 322. The shield material 325 may include a resist material, such as a photoresist, which may be deposited over the second seed layer 322 by any suitable means (for example, a coating method such as spin coating). After deposition, the photoresist may then be patterned, which can change a physical property of a portion of the photoresist. For example, a patterned mask may be arranged over the photoresist, and some portions of the photoresist may be exposed to patterned actinic radiation through the patterned mask. Some portions of the photoresist (either the exposed portions or the non-exposed portions, depending on the chemistry) can then be removed through a developing process to form openings in the photoresist layer. As shown in FIG. 3L, the shield material 325 (e.g., photoresist) is patterned such that there are apertures in the shield material 325 that are aligned with the filled cavities 324.

At 270, a second conductive layer is deposited over the second seed layer. FIG. 3M illustrates the assembly of FIG. 3L after depositing a second conductive layer 326 over the second seed layer 322. As shown, the second conductive layer 326 is deposited within the apertures in the shield material 325 that are aligned with the filled cavities 324, thereby covering portions of the second seed layer 322 over the filled cavities 324. The shield material 325 may prevent the second conductive layer 326 from being deposited over other portions of the second seed layer 322 not aligned with the filled cavities 314B. The second conductive layer 326 may include the same conductive material 309 as the first conductive layer 318 (e.g., copper or another conductive material), or may include a different conductive material. The second conductive layer 326 may be deposited over the second seed layer 322 in the same or a similar manner to the manner described above in which the first conductive layer 318 may be deposited over the first seed layer 316 (e.g., electrolytic and/or electroless plating). The second conductive layer 326 over the filled cavities 324 forms TSSVs 331, e.g., the TSSVs 159 of FIG. 1.

At 275, material is removed from the second preliminary support structure. FIG. 3N illustrates the assembly of FIG. 3M after removing material from the second preliminary support structure 312B. In particular, as shown, the shield material 325 and a portion of the second seed layer 322 may be removed from a side or surface of the second preliminary support structure 312B (e.g., the bottom side of the second preliminary support structure 312B). In some embodiments, the shield material 325 may be removed by any suitable technique. In some embodiments, the shield material 325 may be removed using an etching process (e.g., a wet etching process and/or a dry etching process). In some embodiments, the shield material 325 may be removed in a first process (e.g., using a first etch chemistry), and then a portion of the second seed layer 322 is removed. In particular, the portion of the second seed layer 322 substantially not aligned with the filled cavities 324, and not covered by the second conductive layer 326, may be removed using an etching process (e.g., a wet or dry etching process). A portion of the second conductive layer 326 substantially aligned with the filled cavities 324 may also be removed in the process for removing the portion of the second seed layer 322. However, as shown in FIG. 3N, at least a portion of the second conductive layer 326 remains over the portion of the second seed layer 322 substantially aligned with the filled cavities 324. After the removal of the shield material 325, a portion of the second seed layer 322, a portion of the second conductive layer 326, and/or the bottom side of the second preliminary support structure 312B may be cleaned in order to remove dust, particulates, or debris (e.g., dust, particulates, or debris generated by the removal process).

At 280, an additional layer is placed over the second preliminary support structure. FIG. 3O illustrates the assembly of FIG. 3N after placing an additional layer 328 over the second preliminary support structure 312B (e.g., over the bottom side of the second preliminary support structure 312B). The additional layer 328 may include a dielectric material 329. The dielectric material 329 may include the same material or a similar material as the dielectric material 160 of the additional layer 161 described above with reference to FIG. 1. The additional layer 328 may be placed over the second preliminary support structure 312B using any suitable means (for example, a coating method such as spin coating). In some embodiments, after placement of the additional layer 328, the bottom side of the second preliminary support structure 312B may be planarized using CMP or any other suitable process. The planarization may expose the TSSVs 331 at the bottom of the second preliminary support structure 312B. After planarization, the additional layer 328 may be substantially level or flush with the bottom side or surface of the TSSVs 331.

For ease of illustration and discussion, FIG. 3O-3T show simplified TSSVs 331 (including conductive material 309 surrounding, encasing, or enclosing filler material 321) extending through the second adhesive layer 310B, second preliminary support structure 312B, and additional layer 328. However, it may be understood that the TSSVs 331 comprise the first seed layer 316, the first conductive layer 318, the filler layer 320, the second seed layer 322, and the second conductive layer 326.

At 285, the second interstitial layer is removed from the second preliminary substrate. FIG. 3P illustrates the assembly of FIG. 3O after removing the second interstitial layer 304B from the second preliminary substrate 301B (e.g., a top of the second preliminary substrate 301B). The second interstitial layer 304B may be removed from the second preliminary substrate 301B by any suitable technique. For example, the second interstitial layer 304B may be separated (e.g., peeled, debonded, or delaminated) from the second preliminary substrate 301B by using a blade, an adhesive pad or roller tool, and/or one or more vacuum or suction tools to force apart the second interstitial layer 304B and the second preliminary substrate 301B, using a laser or an etchant to physically or chemically modify or destroy a bond or interface between the second interstitial layer 304B and the second preliminary substrate 301B, and/or another separation method.

At 290, a bridge cavity is formed in the surface (e.g., the top surface) of the second preliminary substrate. FIG. 3Q illustrates the assembly of FIG. 3P after forming a bridge cavity 330 in the top surface of the second preliminary substrate 301B. As shown, after formation of the bridge cavity 330, conductive bridge cavity contacts 332 (e.g., conductive features in the second preliminary substrate 301B) in the bridge cavity 330 may be exposed. The bridge cavity 330 may be formed using any suitable means. For example, the bridge cavity 330 may be formed by drilling, cutting, laser ablating, or chemically etching the second preliminary substrate 301B, and/or otherwise removing a portion of the second preliminary substrate 301B.

At 295, a bridge component is provided in the bridge cavity. FIG. 3R illustrates the assembly of FIG. 3Q after providing a bridge component 334 (e.g., bridge die) in the bridge cavity 330. The bridge component 334 may be the same as or similar to the bridge die 114-1 described with respect to FIG. 1. The bridge component 334 includes first conductive bridge contacts 335 (e.g., at the bottom face of the bridge component 334), second conductive bridge contacts 338 (e.g., at the top face of the bridge component 334), and conductive pathways 336 (e.g., bridge vias) formed therein (e.g., between the first conductive bridge contacts 335 and the second conductive bridge contacts 338). In particular, the first conductive bridge contacts 335 may be joined to the conductive bridge cavity contacts 332 in the bridge cavity 330. The first conductive bridge contacts 335 may be joined to the conductive bridge cavity contacts 332 by BTS interconnects 337. The BTS interconnects 337 may be the same as or similar to the BTS interconnects 151 described above with reference to FIG. 1. The BTS interconnects 337 may comprise a conductive material 355. The conductive material 355 may be the same as or similar to the conductive material 129 described above with reference to FIG. 1. An underfill layer 339 (e.g., the same as or similar to the underfill layer 115 described above with reference to FIG. 1) may be deposited around the BTS interconnects 337 between the bridge component 334 and the second preliminary substrate 301B (e.g., the surface of the second preliminary substrate 301B in which the conductive bridge cavity contacts 332 are present). The underfill layer 339 may include an underfill material 357, which may be the same as or similar to the underfill material 127 described above with reference to FIG. 1.

At 296, dielectric material is provided over the second preliminary substrate 301B (e.g., a top surface of the second preliminary substrate 301B). At 297, conductive features are formed in and over the provided dielectric material. FIG. 3S illustrates the assembly of FIG. 3R after providing dielectric material 307 over the top surface of the second preliminary substrate 301B (e.g., including over the top surface of the bridge component 334, second conductive bridge contacts 338, and in a remaining portion of the bridge cavity 330 not occupied by the underfill layer 339, the BTS interconnects 337, and/or the bridge component 334). The provided dielectric material 307 forms a third dielectric material layer 306C that may be the same as or similar to the second dielectric material layer 113B described above with reference to FIG. 1. FIG. 3S further illustrates the assembly after additional conductive features (e.g., conductive lines/traces/pads/contacts/vias) comprising the same conductive material 309 or a similar conductive material are formed in and on the third dielectric material layer 306C.

At 298, one or more electronic components are joined to the bridge component. At 299, a package substrate is joined to the assembly. FIG. 3T illustrates the assembly of FIG. 3S after joining one or more electronic components (here, two dies 350-1, 350-2) to the bridge component 334. In particular, DTS interconnects 344 (e.g., the same as or similar to the DTS interconnects 140 described above with respect to FIG. 1) comprising a conductive material (e.g., the same as or similar to the conductive material 355 described above), along with DTD interconnects 348 (e.g., the same as or similar to the DTD interconnects 130 described above with respect to FIG. 1) comprising a conductive material (e.g., the same as or similar to the conductive material 355 described above) may be deposited and processed as appropriate (e.g., for solder-based interconnects, subjected to thermal reflow) to join the additional conductive features (e.g., pads) at the top of the second preliminary substrate 301B with conductive features (e.g., pads) at the bottoms of the dies 350-1, 350-2. An underfill layer 340 (e.g., the same as or similar to the underfill layer 339 described above) may be deposited around the DTS interconnects 344 and the DTD interconnects 348 between the second preliminary substrate 301B (e.g., the top surface of the second preliminary substrate 301B) and the dies 350-1, 350-2. FIG. 3T further illustrates the assembly after a package substrate 352 (e.g., the same as or similar to the package substrate 102 described above with reference to FIG. 1) is joined to the assembly. In particular, STPS interconnects 346 (e.g., the same as or similar to the STPS interconnects 150 described above with respect to FIG. 1) comprising a conductive material (e.g., the same as or similar to the conductive material 355 described above) may be deposited and processed as appropriate (e.g., for solder-based interconnects, subjected to thermal reflow) to join the TSSVs 331 (e.g., at the second conductive layer 326 of the TSSVs 331, which may serve as an electrical contact) with conductive features (e.g., pads) at the top of the package substrate 352. An underfill layer 342 (e.g., the same as or similar to the underfill layer 340 described above) may be deposited around the STPS interconnects 150 between the additional layer 328 and the package substrate 352.

FIG. 3T includes four example vias 408-1, 408-2, 408-3, 408-4 in the second preliminary substrate 301B. The vias 408-1, 408-2, 408-3, 408-4 may have substantially conical or frustoconical shapes that taper towards one side (e.g., a top or bottom side) of the second preliminary substrate 301B, or towards and may have various widths (e.g., diameters).

FIG. 4A shows a zoomed view of a first area in the second preliminary substrate 301B shown in FIG. 3T, which includes the via 408-1 and a surrounding portion of the third dielectric material layer 306C. As shown in FIG. 3T, the via 408-1 is located between the bridge component 334 and a DTD interconnect 348, and has a first end (i.e., top end) along a first face (i.e., top face) of the second preliminary substrate 301B and a second end (i.e., bottom end) opposite the first end. Referring back to FIG. 4A, the first end has a first width 410-1 and the second end has a second width 410-2. The first width 410-1 is greater than the second width 410-2. The via 408-1 tapers (i.e., decreases in width) from the first end to the second end (e.g., towards a second face (i.e., bottom face) of the second preliminary substrate 301B). As shown in FIG. 3T, the via 408-1 is above the bridge component 334, and is substantially coplanar with at least one plane perpendicular to a top (e.g. closest to the first face or top face) or bottom (e.g. closest to the second face or bottom face) surface of the bridge component 334.

FIG. 4B shows a zoomed view of a second area in the second preliminary substrate 301B shown in FIG. 3T, which includes the via 408-2 and a surrounding portion of the second dielectric material layer 306B. As shown in FIG. 3T, the via 408-2 is located below the bridge component 334, and has a first end along the second face (i.e., bottom face) of the second preliminary substrate 301B and a second end (i.e., top end) opposite the first end. Referring back to FIG. 4B, the first end has a first width 410-3 and the second end has a second width 410-4. The first width 410-3 is greater than the second width 410-4. The via 408-2 tapers from the first end to the second end (e.g., towards the first face (i.e., top face) of the second preliminary substrate 301B). As shown in FIG. 3T, the via 408-2 is below the bridge component 334, and is substantially coplanar with at least one plane perpendicular to a top (e.g. closest to the first face or top face) or bottom (e.g. closest to the second face or bottom face) surface of the bridge component 334.

FIG. 4C shows a zoomed view of a third area in the second preliminary substrate 301B shown in FIG. 3T, which includes the via 408-3 and a surrounding portion of the third dielectric material layer 306C. As shown in FIG. 3T, the via 408-3 is located under a DTS interconnect 344, and has a first end (i.e., top end) along the first face (i.e., top face) of the second preliminary substrate 301B and a second end (i.e., bottom end) opposite the first end. Referring back to FIG. 4C, the first end has a first width 410-5 and the second end has a second width 410-6. The first width 410-5 is greater than the second width 410-6. The via 408-3 tapers from the first end to the second end (e.g., towards the second face (i.e., bottom face) of the second preliminary substrate 301B). As shown in FIG. 3T, the via 408-3 is not directly above or below the bridge component 334, and is outside of any plane perpendicular to the top or bottom surface of the bridge component 334.

FIG. 4D shows a zoomed view of a fourth area in the second preliminary substrate 301B shown in FIG. 3T, which includes the via 408-4 and a surrounding portion of the second dielectric material layer 306B. As shown in FIG. 3T, the via 408-4 is located in the second dielectric material layer 306B, and has a first end (i.e., bottom end) along the second face (i.e., bottom face) of the second preliminary substrate 301B and a second end (i.e., top end) opposite the first end. Referring back to FIG. 4D, the first end has a first width 410-7 and the second end has a second width 410-8. The first width 410-7 is greater than the second width 410-8. The via 408-4 tapers from the first end to the second end (e.g., towards the first face (i.e., top face) of the second preliminary substrate 301B). As shown in FIG. 3T, the via 408-4 is not directly above or below the bridge component 334, and is outside of any plane perpendicular to the top or bottom surface of the bridge component 334.

In some embodiments, the first width 410-1 of the via 408-1 may be greater than the second width 410-4 of the via 408-2, or greater than the second width 410-6 of the via 408-3, or greater than the second width 410-8 of the via 408-4. In some embodiments, the second width 410-2 of the via 408-1 may be less than the first width 410-3 of the via 408-2, or less than the first width 410-5 of the via 408-3, or less than the first width 410-7 of the via 408-4. In some embodiments, the first width 410-3 of the via 408-2 may be greater than the second width 410-6 of the via 408-3, or greater than the second width 410-8 of the via 408-4. In some embodiments, the second width 410-4 of the via 408-2 may be less than the first width 410-5 of the via 408-3, or less than the first width 410-7 of the via 408-4. In some embodiments, the first width 410-5 of the via 408-3 may be less than the second width 410-8 of the via 408-4. In some embodiments, the second width 410-6 of the via 408-3 may be less than the first width 410-7 of the via 408-4.

The microelectronic assemblies disclosed herein may be included in any suitable electronic component. FIGS. 5-8 illustrate various examples of apparatuses that may include, or be included in, any of the microelectronic assemblies disclosed herein.

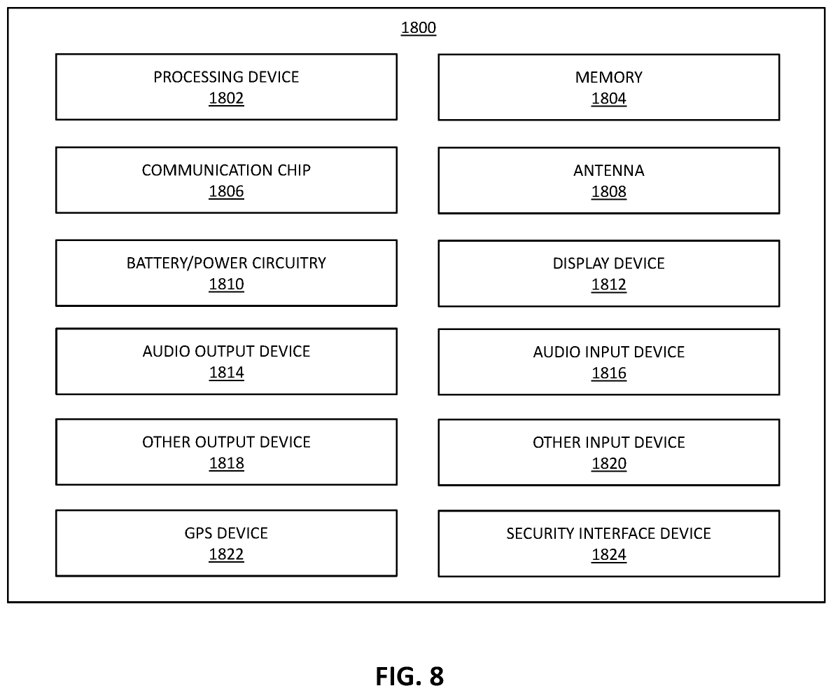

FIG. 5 is a top view of a wafer 1500 and dies 1502 that may be included in any of the microelectronic assemblies disclosed herein (e.g., as any suitable ones of the dies 114). The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may be any of the dies 114 disclosed herein. The die 1502 may include one or more transistors (e.g., some of the transistors 1640 of FIG. 6, discussed below), supporting circuitry to route electrical signals to the transistors, passive components (e.g., signal traces, resistors, capacitors, or inductors), and/or any other IC components. In some embodiments, the wafer 1500 or the die 1502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 8) or other logic that is configured to store information in the memory devices or execute instructions stored in the memory array. In some embodiments, a die 1502 (e.g., a die 114) may be a central processing unit, a radio frequency chip, a power converter, or a network processor. Various ones of the microelectronic assemblies disclosed herein may be manufactured using a die-to-wafer assembly technique in which some dies 114 are attached to a wafer 1500 that include others of the dies 114, and the wafer 1500 is subsequently singulated.

FIG. 6 is a cross-sectional side view of an IC device 1600 that may be included in any of the microelectronic assemblies disclosed herein (e.g., in any of the dies 114). One or more of the IC devices 1600 may be included in one or more dies 1502 (FIG. 5). The IC device 1600 may be formed on a die substrate 1602 (e.g., the wafer 1500 of FIG. 5) and may be included in a die (e.g., the die 1502 of FIG. 5). The die substrate 1602 may be a semiconductor substrate composed of semiconductor material systems including, for example, n-type or p-type materials systems (or a combination of both). The die substrate 1602 may include, for example, a crystalline substrate formed using a bulk silicon or a silicon-on-insulator (SOI) substructure. In some embodiments, the die substrate 1602 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1602. Although a few examples of materials from which the die substrate 1602 may be formed are described here, any material that may serve as a foundation for an IC device 1600 may be used. The die substrate 1602 may be part of a singulated die (e.g., the dies 1502 of FIG. 5) or a wafer (e.g., the wafer 1500 of FIG. 5).

The IC device 1600 may include one or more device layers 1604 disposed on the die substrate 1602. The device layer 1604 may include features of one or more transistors 1640 (e.g., metal-oxide-semiconductor field effect transistors (MOSFETs)) formed on the die substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 6 and may include a wide variety of other types and configurations such as, for example, planar transistors, non-planar transistors, or a combination of both. Non-planar transistors may include fin field effect transistors (FinFETs), such as double-gate transistors or tri-gate transistors, and wrap-around or all-around gate transistors, such as nanoribbon and nanowire transistors.

Each transistor 1640 may include a gate 1622 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1640 is to be a P-type metal-oxide-semiconductor (PMOS) or a N-type metal-oxide-semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1640 along the source-channel-drain direction, the gate electrode may consist of a U-shaped structure that includes a bottom portion substantially parallel to the surface of the die substrate 1602 and two sidewall portions that are substantially perpendicular to the top surface of the die substrate 1602. In other embodiments, at least one of the metal layers that form the gate electrode may simply be a planar layer that is substantially parallel to the top surface of the die substrate 1602 and does not include sidewall portions substantially perpendicular to the top surface of the die substrate 1602. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching. In some embodiments, a plurality of spacer pairs may be used; for instance, two pairs, three pairs, or four pairs of sidewall spacers may be formed on opposing sides of the gate stack.

The S/D regions 1620 may be formed within the die substrate 1602 adjacent to the gate 1622 of each transistor 1640. The S/D regions 1620 may be formed using an implantation/diffusion process or an etching/deposition process, for example. In the former process, dopants such as boron, aluminum, antimony, phosphorous, or arsenic may be ion-implanted into the die substrate 1602 to form the S/D regions 1620. An annealing process that activates the dopants and causes them to diffuse farther into the die substrate 1602 may follow the ion-implantation process. In the latter process, the die substrate 1602 may first be etched to form recesses at the locations of the S/D regions 1620. An epitaxial deposition process may then be carried out to fill the recesses with material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620.

Electrical signals, such as power and/or input/output (I/O) signals, may be routed to and/or from the devices (e.g., transistors 1640) of the device layer 1604 through one or more interconnect layers disposed on the device layer 1604 (illustrated in FIG. 6 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form a metallization stack (also referred to as an “ILD stack”) 1619 of the IC device 1600.

The interconnect structures 1628 may be arranged within the interconnect layers 1606-1610 to route electrical signals according to a wide variety of designs; in particular, the arrangement is not limited to the particular configuration of interconnect structures 1628 depicted in FIG. 6. Although a particular number of interconnect layers 1606-1610 is depicted in FIG. 6, embodiments of the present disclosure include IC devices having more or fewer interconnect layers than depicted.

In some embodiments, the interconnect structures 1628 may include lines 1628a and/or vias 1628b filled with an electrically conductive material such as a metal. The lines 1628a may be arranged to route electrical signals in a direction of a plane that is substantially parallel with a surface of the die substrate 1602 upon which the device layer 1604 is formed. For example, the lines 1628a may route electrical signals in a direction in and out of the page from the perspective of FIG. 6. The vias 1628b may be arranged to route electrical signals in a direction of a plane that is substantially perpendicular to the surface of the die substrate 1602 upon which the device layer 1604 is formed. In some embodiments, the vias 1628b may electrically couple lines 1628a of different interconnect layers 1606-1610 together.

The interconnect layers 1606-1610 may include a dielectric material 1626 disposed between the interconnect structures 1628, as shown in FIG. 6. In some embodiments, the dielectric material 1626 disposed between the interconnect structures 1628 in different ones of the interconnect layers 1606-1610 may have different compositions; in other embodiments, the composition of the dielectric material 1626 between different interconnect layers 1606-1610 may be the same.

A first interconnect layer 1606 (referred to as metal 1 or “M1”) may be formed directly on the device layer 1604. In some embodiments, the first interconnect layer 1606 may include lines 1628a and/or vias 1628b, as shown. The lines 1628a of the first interconnect layer 1606 may be coupled with contacts (e.g., the S/D contacts 1624) of the device layer 1604.

A second interconnect layer 1608 (referred to as metal 2 or “M2”) may be formed directly on the first interconnect layer 1606. In some embodiments, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual damascene process) in some embodiments.

A third interconnect layer 1610 (referred to as metal 3 or “M3”) (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the IC device 1600 (i.e., farther away from the device layer 1604) may be thicker.

The IC device 1600 may include a solder resist material 1634 (e.g., polyimide or similar material) and one or more conductive contacts 1636 formed on the interconnect layers 1606-1610. In FIG. 6, the conductive contacts 1636 are illustrated as taking the form of bond pads. The conductive contacts 1636 may be electrically coupled with the interconnect structures 1628 and configured to route the electrical signals of the transistor(s) 1640 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606-1610; for example, the conductive contacts 1636 may include other analogous features (e.g., posts) that route the electrical signals to external components.

In some embodiments in which the IC device 1600 is a double-sided die (e.g., like the die 114-1), the IC device 1600 may include another metallization stack (not shown) on the opposite side of the device layer(s) 1604. This metallization stack may include multiple interconnect layers as discussed above with reference to the interconnect layers 1606-1610, to provide conductive pathways (e.g., including conductive lines and vias) between the device layer(s) 1604 and additional conductive contacts (not shown) on the opposite side of the IC device 1600 from the conductive contacts 1636.

In other embodiments in which the IC device 1600 is a double-sided die (e.g., like the die 114-1), the IC device 1600 may include one or more TSVs through the die substrate 1602; these TSVs may make contact with the device layer(s) 1604, and may provide conductive pathways between the device layer(s) 1604 and additional conductive contacts (not shown) on the opposite side of the IC device 1600 from the conductive contacts 1636.

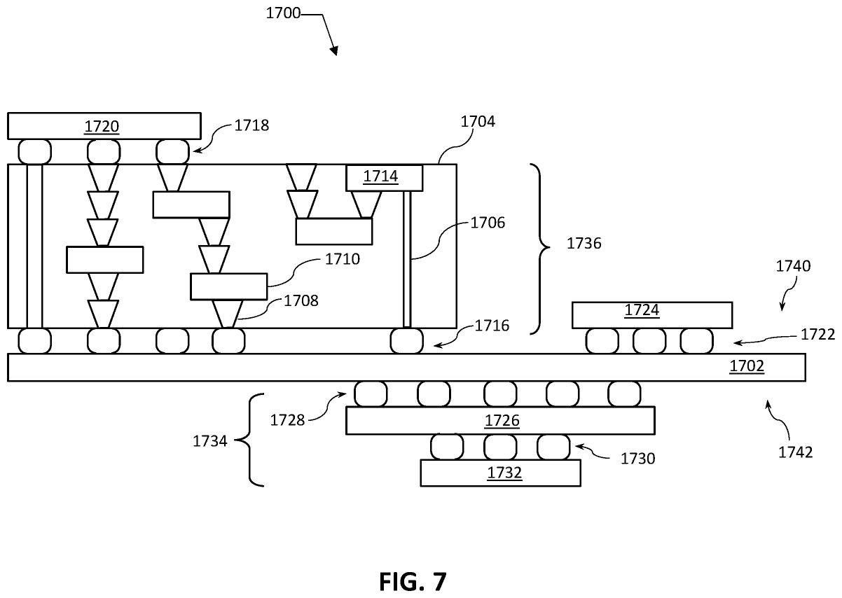

FIG. 7 is a cross-sectional side view of an IC device assembly 1700 that may include any of the microelectronic assemblies disclosed herein. In some embodiments, the IC device assembly 1700 may be the microelectronic assembly 100. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any suitable ones of the embodiments of the microelectronic assemblies disclosed herein.

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate. In some embodiments the circuit board 1702 may be, for example, a circuit board.

The IC device assembly 1700 illustrated in FIG. 7 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 7), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 7, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 5), an IC device (e.g., the IC device 1600 of FIG. 6), or any other suitable component. Generally, the interposer 1704 may spread a connection to a wider pitch or reroute a connection to a different connection. For example, the interposer 1704 may couple the IC package 1720 (e.g., a die) to a set of ball grid array (BGA) conductive contacts of the coupling components 1716 for coupling to the circuit board 1702. As illustrated in FIG. 7, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

In some embodiments, the interposer 1704 may be formed as a PCB, including multiple metal layers separated from one another by layers of dielectric material and interconnected by electrically conductive vias. In some embodiments, the interposer 1704 may be formed of an epoxy resin, a fiberglass-reinforced epoxy resin, an epoxy resin with inorganic fillers, a ceramic material, or a polymer material such as polyimide. In some embodiments, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 7 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 8 is a block diagram of an example electrical device 1800 that may include one or more of the microelectronic assemblies disclosed herein. For example, any suitable ones of the components of the electrical device 1800 may include one or more of the IC device assemblies 1700, IC devices 1600, or dies 1502 disclosed herein, and may be arranged in any of the microelectronic assemblies disclosed herein. A number of components are illustrated in FIG. 8 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 8, but the electrical device 1800 may include interface circuitry for coupling to the one or more components. For example, the electrical device 1800 may not include a display device 1812, but may include display device interface circuitry (e.g., a connector and driver circuitry) to which a display device 1812 may be coupled. In another set of examples, the electrical device 1800 may not include an audio input device 1816 or an audio output device 1814, but may include audio input or output device interface circuitry (e.g., connectors and supporting circuitry) to which an audio input device 1816 or audio output device 1814 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random access memory (STT-MRAM).

In some embodiments, the electrical device 1800 may include a communication chip 1806 (e.g., one or more communication chips). For example, the communication chip 1806 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1806 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as Worldwide Interoperability for Microwave Access (WiMAX) networks, which is a certification mark for products that pass conformity and interoperability tests for the IEEE 802.16 standards. The communication chip 1806 may operate in accordance with a Global System for Mobile Communication (GSM), General Packet Radio Service (GPRS), Universal Mobile Telecommunications System (UMLS), High Speed Packet Access (HSPA), Evolved HSPA (E-HSPA), or LTE network. The communication chip 1806 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1806 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1806 may operate in accordance with other wireless protocols in other embodiments. The electrical device 1800 may include an antenna 1808 to facilitate wireless communications and/or to receive other wireless communications (such as AM or FM radio transmissions).

In some embodiments, the communication chip 1806 may manage wired communications, such as electrical, optical, or any other suitable communication protocols (e.g., the Ethernet). As noted above, the communication chip 1806 may include multiple communication chips. For instance, a first communication chip 1806 may be dedicated to shorter-range wireless communications such as Wi-Fi or Bluetooth, and a second communication chip 1806 may be dedicated to longer-range wireless communications such as global positioning system (GPS), EDGE, GPRS, CDMA, WiMAX, LTE, EV-DO, or others. In some embodiments, a first communication chip 1806 may be dedicated to wireless communications, and a second communication chip 1806 may be dedicated to wired communications.

The electrical device 1800 may include battery/power circuitry 1810. The battery/power circuitry 1810 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1812 (or corresponding interface circuitry, as discussed above). The display device 1812 may include any visual indicators, such as a heads-up display, a computer monitor, a projector, a touchscreen display, a liquid crystal display (LCD), a light-emitting diode display, or a flat panel display.

The electrical device 1800 may include an audio output device 1814 (or corresponding interface circuitry, as discussed above). The audio output device 1814 may include any device that generates an audible indicator, such as speakers, headsets, or earbuds.

The electrical device 1800 may include an audio input device 1816 (or corresponding interface circuitry, as discussed above). The audio input device 1816 may include any device that generates a signal representative of a sound, such as microphones, microphone arrays, or digital instruments (e.g., instruments having a musical instrument digital interface (MIDI) output).

The electrical device 1800 may include a GPS device 1822 (or corresponding interface circuitry, as discussed above). The GPS device 1822 may be in communication with a satellite-based system and may receive a location of the electrical device 1800, as known in the art.

The electrical device 1800 may include a security interface device 1824 (or corresponding interface circuitry, as discussed above). The security interface device 1824 may include any device that provides security features for the electrical device 1800 or for any individual components therein (e.g., for the processing device 1802 or for the memory 1804). Examples of security features may include authorization, access to digital certificates, access to items in keychains, etc. Examples of the security interface device 1824 may include a software firewall, a hardware firewall, an antivirus, a content filtering device, or an intrusion detection device.

The electrical device 1800 may include an other output device 1818 (or corresponding interface circuitry, as discussed above). Examples of the other output device 1818 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a computing device or a hand-held, portable or mobile computing device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server, or other networked computing component, a printer, a scanner, a monitor, a set-top box, an entertainment control unit, a vehicle control unit, a digital camera, a digital video recorder, or a wearable computing device. In some embodiments, the electrical device 1800 may be any other electronic device that processes data.

The following paragraphs provide various examples of the embodiments disclosed herein.

Example 1 provides an assembly including a substrate over a support structure; a bridge component in the substrate; and a via within the substrate, the via between the bridge component and the support structure, where the via has a first end having a first width and a second end having a second width, the first end of the via is closer to the support structure than the second end of the via, and the first width is greater than the second width.

Example 2 provides the assembly of example 1, where the via is a first via, and the assembly further includes a second via in the substrate, the second via arranged on an opposite side of the bridge component from the first via, the second via having a first end having a third width and a second end having a fourth width, the first end of the second via is closer to the bridge component than the second end of the second via, and the third width is less than the fourth width.

Example 3 provides the assembly of examples 1 or 2, where the assembly further includes a through-support structure via (TSSV) within the support structure.

Example 4 provides the assembly of example 3, where the TSSV includes a conductive material and a filler, the filler surrounded by the conductive material.

Example 5 provides the assembly of example 4, where the filler includes a dielectric material.

Example 6 provides the assembly of any one of examples 3-5, where the via is directly coupled to the TSSV.

Example 7 provides the assembly of any one of examples 3-6, where the TSSV extends from a first side of the support structure to a second side of a support structure.

Example 8 provides the assembly of any one of examples 3-7, where the TSSV is a first TSSV, the assembly further including a second TSSV adjacent to the first TSSV, the first TSSV and the second TSSV having a pitch less than 1 millimeter.

Example 9 provides the assembly of any one of claims 3-8, further including an adhesive between the support structure and the substrate, where the adhesive is present along a region of the support structure outside of the TSSV.

Example 10 provides the assembly of any one of examples 1-9, further including a layer between the support structure and the substrate.

Example 11 provides the assembly of any one of examples 1-10, where the support structure includes glass.

Example 12 provides the assembly of example 11, where the glass includes one or more of a soda-lime glass, a borosilicate glass, an aluminosilicate glass, an alkali borosilicate glass, an aluminoborosilicate glass, and an alkali aluminosilicate glass.

Example 13 provides the assembly of any one of examples 1-12, where the support structure is less than 1 millimeter in thickness.

Example 14 provides an assembly including a substrate; a glass layer (e.g., a support structure) at a face of the substrate (e.g., joined to the face of the substrate); a first conductive structure in the substrate, where an end of the first conductive structure is along the face of the substrate; and a second conductive structure extending within the support structure, the second conductive structure directly coupled to the first conductive structure.

Example 15 provides the assembly of example 14, where the second conductive structure includes a conductive material surrounding a dielectric material.

Example 16 provides the assembly of examples 14 or 15, further including a patterned layer between the substrate and the glass layer.

Example 17 provides the assembly of example 16, where the patterned layer is an adhesive layer, and the second conductive structure extends through the adhesive layer.

Example 18 provides the assembly of any one of examples 14-17, where the second conductive structure includes a seed layer.

Example 19 provides the assembly of any one of examples 14-18, where the second conductive structure includes a first end and a second end, the first end of the second conductive structure is closer to the substrate than the second end of the second conductive structure, and the first end of the second conductive structure has a first width that is less than a second width of the second end of the second conductive structure.

Example 20 provides a device (e.g., a semiconductor package) including a substrate having a first side and a second side opposite the first side; an electronic component at the first side of the substrate; a bridge die in the substrate, the bridge die electrically coupled to the electronic component; a glass support at the second side of the substrate; and a via within the substrate, the via between the bridge die and the glass support, where the via has a first end having a first width and a second end having a second width, the first end of the via is closer to the glass support than the second end of the via, and the first width is greater than the second width.

Example 21 provides the device of example 20, where the via is a first via, and the device further includes a second via, the second via within the glass support.

Example 22 provides the device of example 21, where the second via includes a conductive material and a dielectric filler, the dielectric filler surrounded by the conductive material.

Example 23 provides an assembly (e.g., a semiconductor assembly), including a substrate over a support structure, the substrate having a first face and a second face, the first face further from the support structure than the second face; a bridge component in the substrate; a first via within the substrate, the first via having a first end along the first face of the substrate and a second end opposite the first end, the first via tapering towards the second end; and a second via within the substrate, the second via having a third end along the second face of the substrate and a fourth end opposite the third end, the second via tapering towards the fourth end.

Example 24 provides the assembly of example 23, where at least a portion of the first via is substantially coplanar with at least one plane perpendicular to a surface of the bridge component closest to the first face.

Example 25 provides the assembly of example 23, where the first via is outside of any plane perpendicular to a surface of the bridge component closest to the first face.

Example 26 provides the assembly of example 23, where at least a portion of the second via is substantially coplanar with at least one plane perpendicular to a surface of the bridge component closest to the first face.

Example 27 provides the assembly of example 23, where the second via is outside of any plane perpendicular to a surface of the bridge component closest to the first face.

Example 28 provides the assembly of any one of examples 23-27, further including a third via within the support structure.

Example 29 provides the assembly of example 28, where the third via includes a conductive material and a filler, the filler surrounded by the conductive material.

Example 30 provides the assembly of example 29, where the filler includes a dielectric material.

Example 31 provides the assembly of any one of examples 28-30, where the second via is directly coupled to the third via.

Example 32 provides the assembly of any one of examples 28-31, where the third via extends through the support structure.

Example 33 provides the assembly of example 32, where the third via extends through the support structure between a first side of the support structure closest to the substrate and a second side of the support structure opposing the first side of the support structure.

Example 34 provides the assembly of any one of examples 23-33, further including an adhesive between the support structure and the substrate.

Example 35 provides the assembly of example 28, further including an adhesive between the support structure and the substrate, where the third via extends through the support structure, and the adhesive is present along a region of the support structure outside of the third via.

Example 36 provides the assembly of any one of examples 23-35, where the support structure includes glass.

Example 37 provides the assembly of example 36, where the glass includes one or more of a soda-lime glass, a borosilicate glass, an aluminosilicate glass, an alkali borosilicate glass, an aluminoborosilicate glass, and an alkali aluminosilicate glass.

Example 38 provides the assembly of any one of examples 23-37, where the support structure is less than 1 millimeter in thickness.

1. An assembly comprising:
a substrate over a support structure;
a bridge component in the substrate; and
a via within the substrate, the via between the bridge component and the support structure, wherein the via has a first end having a first width and a second end having a second width, the first end of the via is closer to the support structure than the second end of the via, and the first width is greater than the second width.

2. The assembly of claim 1, wherein the via is a first via, and the assembly further comprises:
a second via in the substrate, the second via arranged on an opposite side of the bridge component from the first via, the second via having a first end having a third width and a second end having a fourth width, the first end of the second via is closer to the bridge component than the second end of the second via, and the third width is less than the fourth width.

3. The assembly of claim 1, wherein the assembly further comprises:
a through-support structure via (TSSV) within the support structure.

4. The assembly of claim 3, wherein the TSSV comprises a conductive material and a filler, the filler surrounded by the conductive material.

5. The assembly of claim 4, wherein the filler comprises a dielectric material.

6. The assembly of claim 3, wherein the via is directly coupled to the TSSV.

7. The assembly of claim 3, wherein the TSSV extends from a first side of the support structure to a second side of a support structure.

8. The assembly of claim 3, wherein the TSSV is a first TSSV, the assembly further comprising a second TSSV adjacent to the first TSSV, the first TSSV and the second TSSV having a pitch less than 1 millimeter.

9. The assembly of claim 3, further comprising an adhesive between the support structure and the substrate, wherein the adhesive is present along a region of the support structure outside of the TSSV.

10. The assembly of claim 1, wherein the support structure comprises glass.

11. The assembly of claim 10, wherein the glass comprises one or more of a soda-lime glass, a borosilicate glass, an aluminosilicate glass, an alkali borosilicate glass, an aluminoborosilicate glass, and an alkali aluminosilicate glass.

12. An assembly comprising:
a substrate;
a glass layer at a face of the substrate;
a first conductive structure in the substrate, wherein an end of the first conductive structure is along the face of the substrate; and
a second conductive structure extending within the glass layer, the second conductive structure directly coupled to the first conductive structure.

13. The assembly of claim 12, wherein the second conductive structure comprises a conductive material surrounding a dielectric material.

14. The assembly of claim 12, further comprising a patterned layer between the substrate and the glass layer.

15. The assembly of claim 14, wherein the patterned layer is an adhesive layer, and the second conductive structure extends through the adhesive layer.

16. The assembly of claim 14, wherein the second conductive structure comprises a seed layer.

17. The assembly of claim 14, wherein the second conductive structure comprises a first end and a second end, the first end of the second conductive structure is closer to the substrate than the second end of the second conductive structure, and the first end of the second conductive structure has a first width that is less than a second width of the second end of the second conductive structure.

18. A device comprising:
a substrate having a first side and a second side opposite the first side;
an electronic component at the first side of the substrate;
a bridge die in the substrate, the bridge die electrically coupled to the electronic component;
a glass support at the second side of the substrate; and
a via within the substrate, the via between the bridge die and the glass support, wherein the via has a first end having a first width and a second end having a second width, the first end of the via is closer to the glass support than the second end of the via, and the first width is greater than the second width.

19. The device of claim 18, wherein the via is a first via, and the device further comprises a second via, the second via within the glass support.

20. The device of claim 19, wherein the second via comprises a conductive material and a dielectric filler, the dielectric filler surrounded by the conductive material.
